(19) United States
(12) Patent Application Publication
(10) Pub. No.: US 2026/0053261 A1
(43) Pub. Date: Feb. 26, 2026

(54) WAFER CLEANING DEVICE

(71) Applicant: SAMSUNG ELECTRONICS CO., LTD., Suwon-si (KR)

(72) Inventors: Minki Kim, Suwon-si (KR); Kyoungwhan Oh, Suwon-si (KR); Hoseop Choi, Suwon-si (KR)

(21) Appl. No.: 19/020,835

(22) Filed: Jan. 14, 2025

(30) Foreign Application Priority Data
Aug. 20, 2024 (KR) 10-2024-0111628

(51) Int. Cl. A46B 13/04; A46B 9/00; A46B 9/02; A46B 13/00; A46B 15/00; H01L 21/67

(52) U.S. Cl. CPC A46B 13/04; A46B 9/005; A46B 9/026; A46B 13/003; A46B 15/0014; A46B 2200/3073; H01L 21/67046

(57) ABSTRACT

A wafer cleaning device includes a plurality of brush systems arranged in a line in a first direction and configured to clean a wafer. Each of the plurality of brush systems includes a body having a tube shape extending in the first direction, a nodule arranged on an outer surface of the body, and a driveshaft extending in the first direction and configured to integrally rotate with the body. The plurality of brush systems are configured to independently rotate with the first direction as a rotation axis.

### CROSS-REFERENCE TO RELATED APPLICATIONS

This application claims priority to Korean Patent Application No. 10-2024-0111628, filed in the Korean Intellectual Property Office on Aug. 20, 2024, the disclosure of which is incorporated by reference herein in its entirety.

### BACKGROUND

Numerous processes are carried out to form a desired pattern on the surface of a semiconductor wafer. Unnecessary thin films and various contaminants are formed and remain on the surface of the semiconductor wafer on which a certain process is performed. To remove the unnecessary thin films and various contaminants, the semiconductor wafer needs to be cleaned.

In particular, when a planarization process is performed on a semiconductor wafer by using a chemical mechanical polishing (CMP) device, colloidal abrasive particles contained in polishing slurry remain on the semiconductor wafer. Accordingly, after the CMP process, a cleaning process needs to be carried out to remove agglomerated abrasive particles before a subsequent process is carried out.

For this cleaning process, scrubber cleaning carried out by rotating a brush is usually used. The brush may have a nodule on the outer surface thereof to help clean a wafer. A rotary cylindrical brush needs to engage with a rotating circular wafer, such as a semiconductor wafer. In this case, a friction difference between the rotary cylindrical brush and the circular wafer may be caused by the difference in the linear velocity between a point on the rotary cylindrical brush and a point on the circular wafer.

### SUMMARY

In general, in some aspects, the present disclosure is directed toward a wafer cleaning device capable of preventing damage to elements formed in a wafer and evenly cleaning the entire area of the wafer.

According to some implementations, the present disclosure is directed to a wafer cleaning device including a plurality of brush modules arranged in a line in one direction and configured to clean a wafer, wherein each of the plurality of brush modules includes a body having a tube shape extending in the one direction, a nodule arranged on an outer surface of the body, and a driveshaft extending in the one direction and configured to integrally rotate with the body, and the plurality of brush modules are configured to independently rotate with the one direction as a rotation axis.

According to some implementations, the present disclosure is directed to a wafer cleaning device including a first brush module, a second brush module, and a third brush module that are arranged in a line in one direction and configured to clean a wafer, wherein the first brush module includes a first body having a tube shape extending in the one direction, a first nodule arranged on an outer surface of the first body, and a first driveshaft extending in the one direction and configured to integrally rotate with the first body, the second brush module includes a second body having a tube shape extending in the one direction, a second nodule arranged on an outer surface of the second body, and a second driveshaft extending in the one direction and configured to integrally rotate with the second body, and the third brush module includes a third body having a tube shape extending in the one direction, a third nodule arranged on an outer surface of the third body, and a third driveshaft extending in the one direction and configured to integrally rotate with the third body, wherein the wafer cleaning device further comprises a first fluid supply pipe inside the first body and configured to eject a first fluid to the first body, a second fluid supply pipe inside the second body and configured to eject a second fluid to the second body, and a third fluid supply pipe inside the third body and configured to eject a third fluid to the third body.

According to some implementations, the present disclosure is directed to a wafer cleaning device including a first brush module structure including a first brush module, a second brush module, and a third brush module that are arranged in a line in one direction and configured to clean a wafer; and a second brush module structure including a fourth brush module, a fifth brush module, and a sixth brush module that are arranged from the third brush module in a line in the one direction and configured to clean the wafer, wherein each of the first brush module, the second brush module, the third brush module, the fourth brush module, the fifth brush module, and the sixth brush module includes an inner housing having a tube shape in the one direction, an outer housing extending in the one direction and having a tube shape having a hollow accommodating the inner housing, a body extending in the one direction and having a tube shape having a hollow accommodating the outer housing, a nodule on an outer surface of the body, a driveshaft in the inner housing and configured to integrally rotate with the body, and a fluid supply pipe between the inner housing and the outer housing and configured to eject fluid to the body. The first brush module, the second brush module, the third brush module, the fourth brush module, the fifth brush module, and the sixth brush module are configured to independently rotate with the one direction as a rotation axis, and the respective fluid supply pipes of the first brush module, the second brush module, the third brush module, the fourth brush module, the fifth brush module, and the sixth brush module are configured to independently eject the fluid.

### BRIEF DESCRIPTION OF THE DRAWINGS

Example implementations will be more clearly understood from the following detailed description, taken in conjunction with the accompanying drawings.

FIG. 1 is a plan view illustrating an example of wafer polishing apparatus according to some implementations.

FIG. 2 is a cross-sectional view illustrating an example of a wafer cleaning system according to some implementations.

FIG. 3 is a perspective view illustrating an example of a wafer cleaning system according to some implementations.

FIG. 4 is a plan view illustrating an example of a wafer cleaning device according to some implementations.

FIG. 5 shows examples of nodules of a wafer cleaning device according to some implementations.

FIG. 6 shows cross-sections of examples of wafer cleaning devices according to some implementations.

FIG. 7 shows cross-sections of examples of wafer cleaning devices according to some implementations.

FIG. 8 shows enlarged views of examples of nodules of a wafer cleaning device according to some implementations.

FIG. 9A is a plan view illustrating an example of a wafer cleaning device according to some implementations.

FIG. 9B is a plan view illustrating an example of a first brush structure in FIG. 9A according to some implementations.

FIG. 9C is a cross-sectional view taken along line A-A′ in FIG. 9B according to some implementations.

FIG. 9D is a cross-sectional view taken along line B-B′ in FIG. 9B according to some implementations.

FIG. 9E is a perspective view illustrating an example of a part of the wafer cleaning device of FIG. 9A according to some implementations.

FIG. 9F is a plan view illustrating an example of the second brush structure in FIG. 9A according to some implementations.

FIG. 9G shows a cross-sectional view and a perspective view of an example of a part of the first brush structure in FIG. 9A according to some implementations.

FIG. 10A is a plan view illustrating an example of a wafer cleaning device according to some implementations.

FIG. 10B is a diagram illustrating an example of a controller in FIG. 10A according to some implementations.

FIG. 10C is a plan view illustrating an example of the first brush structure in FIG. 10A according to some implementations.

FIG. 10D is a cross-sectional view taken along line C-C′ in FIG. 10C according to some implementations.

FIG. 10E is a cross-sectional view taken along line D-D′ in FIG. 10C according to some implementations.

FIG. 10F is a perspective view of a part of the first brush structure in FIG. 10A according to some implementations.

FIG. 10G is a plan view illustrating the second brush structure in FIG. 10A according to some implementations.

FIG. 11A is a plan view illustrating an example of a wafer cleaning device according to some implementations.

FIG. 11B is a conceptual diagram illustrating an example of a control system in FIG. 11A according to some implementations.

FIG. 11C is a plan view illustrating an example of the first brush structure in FIG. 11A according to some implementations.

FIG. 11D is a cross-sectional view taken along line E-E′ in FIG. 11C according to some implementations.

FIG. 11E is a cross-sectional view taken along line F-F′ in FIG. 11C according to some implementations.

FIG. 11F is a perspective view of an example of a part of the first brush structure in FIG. 11A according to some implementations.

FIG. 12 is a graph illustrating examples of effects of a wafer cleaning device according to some implementations.

FIG. 13 is a diagram illustrating examples of a relative velocity between a wafer and a brush system according to some implementations.

FIG. 14 is a graph illustrating examples of a relative velocity of a position in the radial direction of a wafer according to some implementations.

FIG. 15 shows graphs illustrating examples of flowrate of fluid and the revolutions per minute (RPM) of a brush system controlled in response to torque applied to the brush module according to some implementations.

### DETAILED DESCRIPTION

Hereinafter, example implementations will be explained in detail with reference to the accompanying drawings.

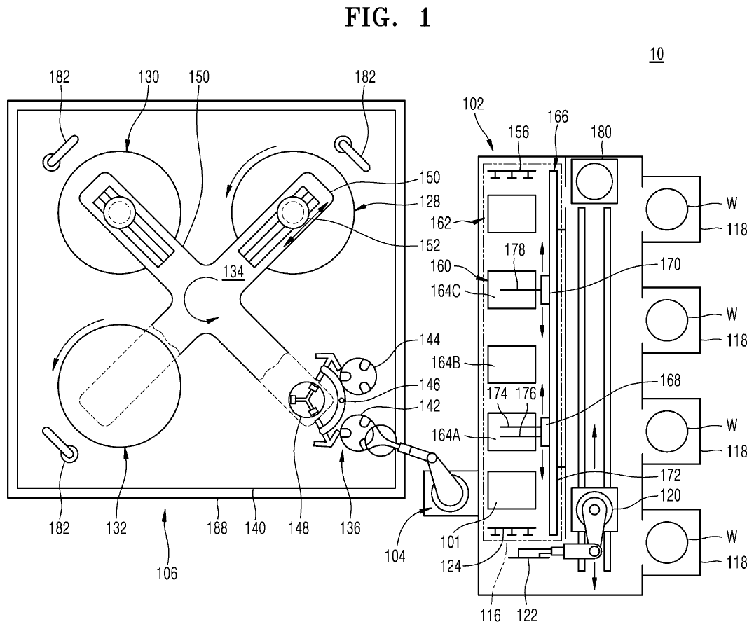

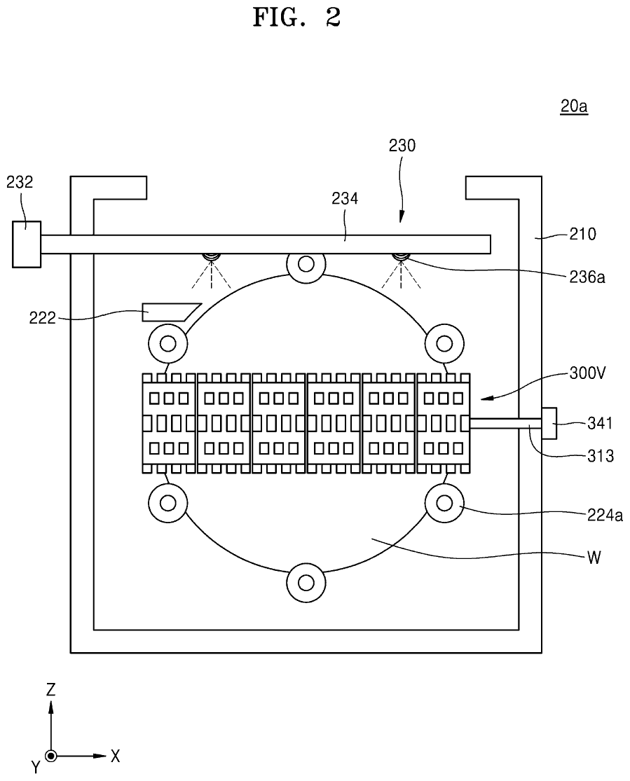

FIG. 1 is a plan view illustrating an example of a wafer polishing apparatus according to some implementations. FIG. 2 is a cross-sectional view illustrating an example of a wafer cleaning system according to some implementations.

In FIG. 1, a wafer polishing apparatus 10 may include a polishing device 106 for polishing the surface of a wafer W and a wafer cleaning system 20a (see FIG. 2) for cleaning the wafer W polished by the polishing device 106. The wafer polishing apparatus 10 may further include a factory interface 102 and a loading robot 104.

The factory interface 102 may include a cleaner 116, a plurality of wafer cassettes 118, an interface robot 120, and a measuring system 180.

The cleaner 116 may include an input device 124, a plurality of cleaning systems 160, a dryer 162, a wafer handler 166 above the cleaning systems 160, and an output device 156.

The input device 124 may act as a transfer station among the factory interface 102, the cleaner 116, and the polishing device 106.

The cleaning systems 160 may include a buffing device 101, a megasonic clearing device 164A, a first wafer cleaning device 164B, and a second wafer cleaning device 164C. Each of the cleaning systems 160 may clean the surface of the wafer W. The number and type of cleaning systems are just examples, and the present disclosure is not limited thereto.

The dryer 162 may dry the wafer W. The wafer W dried by the dryer 162 may be smoothly transferred in the factory interface 102.

While being cleaned, a plurality of wafers W may be moved between the cleaning systems 160 and the dryer 162 by the wafer handler 166. The wafer handler 166 may include a first robot 168 and a second robot 170.

The first robot 168 may include at least one gripper (e.g., 174 and 176). As shown in FIG. 1, the first robot 168 may include a plurality of grippers 174 and 176. The first robot 168 may transfer each of the wafers W between the input device 124 and the cleaning systems 160.

The second robot 170 may include at least one gripper (e.g., 178). As shown in FIG. 1, the second robot 170 may include a gripper 178. The second robot 170 may transfer the wafers W between at least one of the cleaning systems 160 and the dryer 162.

The number of grippers of each of the first robot 168 and the second robot 170 is just an example, and the present disclosure is not limited thereto.

The first robot 168 and the second robot 170 may move in a lateral direction along a rail 172. Accordingly, the wafers W may be moved between the cleaning systems 160 and the dryer 162 by the first robot 168 and the second robot 170 of the wafer handler 166.

A cleaned wafer W may be transferred to the output device 156 by the wafer handler 166. The wafer W transferred to the output device 156 may be tilted by the interface robot 120 to be horizontally oriented. The wafer W may be returned to one of the wafer cassettes 118 by the interface robot 120.

Selectively, before the wafers W are respectively returned to the wafer cassettes 118, the wafers W may be transferred to the measuring system 180 by the interface robot 120 or the wafer handler 166. The wafers W may be tested in the measuring system 180.

The loading robot 104 may be adjacent to the factory interface 102 and the polishing device 106. The loading robot 104 may be between the factory interface 102 and the polishing device 106. The loading robot 104 may transfer the wafers W between the factory interface 102 and the polishing device 106.

The polishing device 106 may include at least one chemical mechanical polishing (CMP) station. The polishing device 106 may include at least one CMP station (e.g., 128, 130, and 132) in an environmentally controlled enclosure 188.

In FIG. 1, the polishing device 106 may include a bulk CMP station 128, a second CMP station 130, and a third CMP station 132.

In the bulk CMP station 128, bulk removal of conductive materials may be performed via a CMP process.

Thereafter, in the second CMP station 130 and the third CMP station 132, a CMP process may be performed on residual conductive materials.

The polishing device 106 may also include, above a machine base 140, a carousel 134, a transfer station 136, and a plurality of conditioning devices 182.

The carousel 134 may be at the center of the machine base 140. The carousel 134 may include a plurality of arms 150. Each of the arms 150 may support a planarizing head assembly 152.

The carousel 134 may be indexable such that the planarizing head assembly 152 may be moved between the CMP stations (e.g., 128, 130, and 132) and the transfer station 136.

The transfer station 136 may include an input buffer station 144, an output buffer station 142, a transfer robot 146, and a load cup assembly 148.

The wafers W may be transferred from the factory interface 102 to the input buffer station 144 by the loading robot 104. The wafers W may be transferred to the input buffer station 144 to be polished by the polishing device 106.

The wafers W may be transferred from the output buffer station 142 to the factory interface 102 by the loading robot 104. The wafers W transferred to the factory interface 102 may have been polished through a CMP process.

The transfer robot 146 may be used to move the wafers W between the output and input buffer stations 142 and 144 and the load cup assembly 148. The transfer robot 146 may include two gripper assemblies. Each of the two gripper assemblies may have pneumatic gripper fingers holding the edge of a wafer W.

A method of holding the wafer W with pneumatic gripper fingers is just an example, and the present disclosure is not limited thereto.

The conditioning devices 182 may be arranged on the machine base 140 to be respectively adjacent to the CMP stations (e.g., 128, 130, and 132). Each of the conditioning devices 182 may periodically condition a planarizing material within one of the CMP stations (e.g., 128, 130, and 132). Accordingly, results of planarizing the wafers W may be maintained uniform.

In FIG. 2, after a CMP process, the wafer cleaning system 20a may be used to clean the wafer W. The wafer cleaning system 20a may correspond to one of the first wafer cleaning device 164B and the second wafer cleaning device 164C in FIG. 1.

According to some implementations, the wafer cleaning system 20a may include a chamber 210, a wafer cleaning device 300V, a support plate 222, a roller 224a, and a cleaning nozzle unit 230.

The wafer cleaning device 300V may include a driveshaft 313, a plurality of brush systems, and an actuator 341.

The brush systems may extend in one direction. The brush systems may have a cylindrical shape. The brush systems may extend in the same direction as a direction in which the driveshaft 313 extends.

The brush systems may be arranged along the circumference of the driveshaft 313. The inner surfaces of the brush systems may be formed along the profile of the surface of the driveshaft 313. Accordingly, the brush systems may be fixed to the driveshaft 313. A method of fixing the brush systems to the driveshaft 313 is just an example, and the present disclosure is not limited thereto.

The actuator 341 may be connected to the driveshaft 313. The actuator 341 may provide torque to the driveshaft 313. The torque provided to the driveshaft 313 by the actuator 341 may be delivered to a brush system in contact with the driveshaft 313. Accordingly, the brush system may rotate by receiving the torque from the actuator 341.

Although FIG. 2 depicts that the actuator 341 is outside the chamber 210, the present disclosure is not limited thereto.

One side of the support plate 222 may be concave along the circumference of a wafer W. The support plate 222 may support the wafer W. The support plate 222 may adjust the position of the wafer W.

The position of the support plate 222 or the number of support plates 222, which is shown in FIG. 2, is just an example, and the present disclosure is not limited thereto.

A plurality of rollers 224a may be arranged along the circumference of the wafer W. Each of the rollers 224a may have a cylindrical shape. A groove may be formed in a center of the cylindrical shape along a circumference thereof.

The wafer W may be in contact with the groove of each roller 224a. The roller 224a may be rotated. Accordingly, the wafer W in contact with the roller 224a may also be rotated.

Although six rollers 224a are arranged in FIG. 2, the present disclosure is not limited thereto.

The cleaning nozzle system 230 may supply a cleaning solution to the wafer W or the wafer cleaning device 300V. The cleaning nozzle system 230 may include a cleaning solution source 232, a cleaning nozzle tube 234 connected to the cleaning solution source 232, and a cleaning nozzle 236a installed in the cleaning nozzle tube 234.

The cleaning solution source 232 may include, but not limited to, a mixture of ammonia, hydrogen peroxide, and deionized water. The wafer W may be easily cleaned by supplying a cleaning solution to the wafer W or the wafer cleaning device 300V through the cleaning nozzle system 230.

In the wafer cleaning system 20a of FIG. 2, the rotation axis of the wafer cleaning device 300V may be perpendicular to the inner wall of the chamber 210. In other words, as illustrated in FIG. 2, the rotation axis of each of the rollers 224a arranged along the circumference of the wafer W may be parallel with a second horizontal direction (a Y direction). The top surface of the chamber 210 may be parallel with the vertical direction (the Z direction). A direction that is perpendicular to both the vertical direction (the Z direction) and the second horizontal direction (the Y direction) may be defined as a first horizontal direction (an X direction).

The axis of each roller 224a may be parallel with the rotation axis of the wafer W supported by the roller 224a. The wafer W surrounded by the rollers 224a configured to be rotatable may be rotated around a rotation axis parallel with the rotation axis of the roller 224a. In FIG. 2, the main surface of the wafer W may be located in the chamber 210 to face the second horizontal direction (the Y direction). The main surface of the wafer W may be defined as a surface on which a semiconductor device is manufactured in the wafer W.

Although only one wafer cleaning device 300V is arranged in the chamber 210 in FIG. 2, a wafer cleaning device may be arranged on each of both the main surface of the wafer W and the back surface opposite to the main surface. Accordingly, at least two wafer cleaning devices may be arranged in the chamber 210.

Because the main surface of the wafer W is parallel with the vertical direction (the Z direction), the wafer cleaning system 20a of FIG. 2 may be referred to as a vertical type wafer cleaning system.

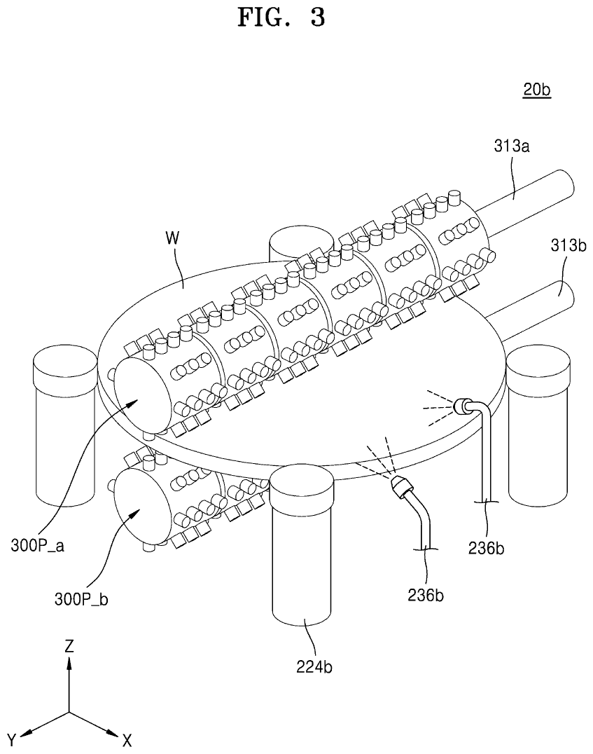

FIG. 3 is a perspective view illustrating an example of a wafer cleaning system according to some implementations. In FIG. 3, a wafer cleaning system 20b is substantially the same as or similar to the wafer cleaning system 20a of FIG. 2, except for the arrangement of the wafer W. The differences from the wafer cleaning system 20a of FIG. 2 are mainly described below.

In FIG. 3, the wafer cleaning system 20b may include a pair of wafer cleaning devices (e.g., 300P_a and 300P_b), a pair of driveshafts 313a and 313b, a roller 224b, and a cleaning nozzle 236b. The pair of wafer cleaning devices (300P_a and 300P_b), the roller 224b, and the cleaning nozzle 236b may be arranged within a chamber, but the chamber is not shown for convenience of illustration.

The main surface of the wafer W may face the vertical direction (the Z direction) in the wafer cleaning system 20b of FIG. 3 unlike the wafer cleaning system 20a of FIG. 2.

In the wafer cleaning system 20b of FIG. 3, the rotation axis of the roller 224b may face the vertical direction (the Z direction). In other words, the rotation axis of the roller 224b arranged along the circumference of the wafer W may be parallel with the vertical direction (the Z direction).

The rotation axis of the roller 224b may be parallel with the rotation axis of the wafer W supported by the roller 224b. The wafer W surrounded by a plurality of rollers 224b configured to rotate may be configured to rotate around the rotation axis parallel with the rotation axis of the rollers 224b. In FIG. 3, the main surface of the wafer W may be within the chamber (not shown) to face the vertical direction (the Z direction).

The pair of wafer cleaning devices (300P_a and 300P_b) may include a first wafer cleaning device 300P_a on the main surface of the wafer W and the second wafer cleaning device 300P_b on the back surface opposite to the main surface of the wafer W. The driveshafts 313a and 313b may be configured to respectively rotate the first wafer cleaning device 300P_a and the second wafer cleaning device 300P_b in one direction.

The driveshafts 313a and 313b may rotate with the second horizontal direction (the Y direction), which is perpendicular to the vertical direction (the Z direction) parallel with the rotation axis of the wafer W, as a rotation axis. The first and second wafer cleaning devices 300P_a and 300P_b may be rotated by the driveshafts 313a and 313b with the second horizontal direction (the Y direction) as a rotation axis.

The cleaning nozzle 236b may be configured to spray a cleaning solution to the main surface of the wafer W. The function and configuration of the cleaning nozzle 236b in FIG. 3 are similar to those of the cleaning nozzle 236a in FIG. 2, and detailed descriptions thereof are omitted.

Because the main surface of the wafer W is parallel with the lateral direction (the X direction and/or the Y direction) in the wafer cleaning system 20b of FIG. 3, the wafer cleaning system 20b may be referred to as a horizontal type wafer cleaning module.

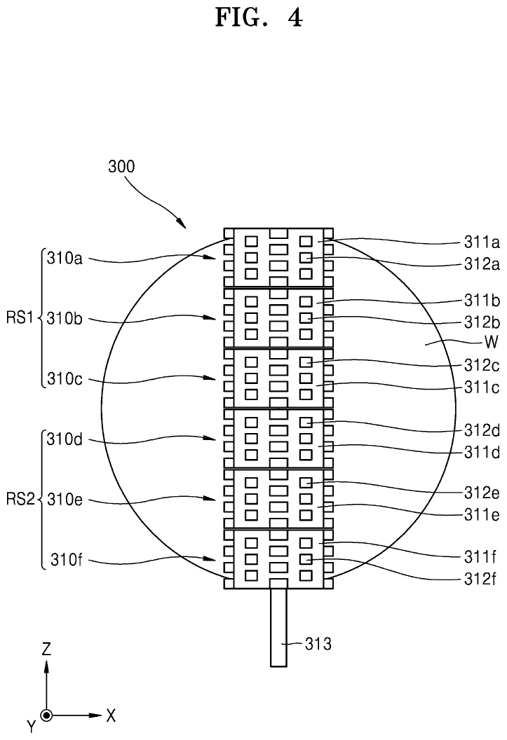

FIG. 4 is a plan view illustrating an example of a wafer cleaning device according to some implementations. In FIG. 4, a wafer cleaning device 300 may correspond to the wafer cleaning device 300V used in the vertical type wafer cleaning module shown in FIG. 2. However, the wafer cleaning device 300 describe below may also be used in a horizontal type wafer cleaning module as well as the vertical type wafer cleaning module.

In FIG. 4, the wafer cleaning device 300 may include a first brush structure RS1, a second brush structure RS2, and a driveshaft 313, which are arranged in a line in one direction.

The first brush structure RS1 may include a first brush system 310a, a second brush system 310b, and a third brush system 310c, which are arranged in a line in a reverse vertical direction (a −Z direction). The second brush structure RS2 may include a fourth brush system 310d, a fifth brush system 310c, and a sixth brush system 310f, which are arranged in a line in the reverse vertical direction (the −Z direction).

Although three brush systems are shown to form one brush structure, this is just an example implementations. The number of brush systems forming a brush structure is not limited thereto.

The first brush system 310a may include a first body 311a and a first nodule 312a. The second brush system 310b may include a second body 311b and a second nodule 312b. The third brush system 310c may include a third body 311c and a third nodule 312c. The fourth brush system 310d may include a fourth body 311d and a fourth nodule 312d. The fifth brush system 310c may include a fifth body 311e and a fifth nodule 312e. The sixth brush system 310f may include a sixth body 311f and a sixth nodule 312f.

The first to sixth bodies 311a to 311f may have a tube shape extending in one direction. In some implementations, there may be a plurality of first nodules 312a. The first nodules 312a may be arranged on the outer surface of the first body 311a. In some implementations, there may be a plurality of second nodules 312b. The second nodules 312b may be arranged on the outer surface of the second body 311b. In some implementations, there may be a plurality of third nodules 312c. The third nodules 312c may be arranged on the outer surface of the first body 311a. In some implementations, there may be a plurality of fourth nodules 312d. The fourth nodules 312d may be arranged on the outer surface of the fourth body 311d. In some implementations, there may be a plurality of fifth nodules 312e. The fifth nodules 312e may be arranged on the outer surface of the fifth body 311e. In some implementations, there may be a plurality of sixth nodules 312f. The sixth nodules 312f may be arranged on the outer surface of the sixth body 311f.

The first to sixth nodules 312a to 312f may come into direct contact with the wafer W while the wafer cleaning device 300 is cleaning the wafer W. During the cleaning of the wafer W, the first to sixth brush systems 310a to 310f may rotate with the vertical direction (the Z direction) as an axis. Simultaneously, the wafer W may rotate with the second horizontal direction (the Y direction), which is perpendicular to the vertical direction (the Z direction), as an axis. Accordingly, the surface of the wafer W may be come into contact with the first to sixth nodules 312a to 312f, which are formed on the surfaces of the first to sixth bodies 311a to 311f, and may be cleaned.

When the first to sixth brush systems 310a to 310f rotate with the vertical direction (the Z direction) as an axis and the wafer W rotates with the second horizontal direction (the Y direction) as an axis, the entire area of the main surface of the wafer W may come into contact with the first to sixth brush systems 310a to 310f.

According to some implementations, the driveshaft 313 may be fastened to the first brush structure RS1 and the second brush structure RS2 and configured to rotate the first brush structure RS1 and the second brush structure RS2 around the central axis of the driveshaft 313.

The first to sixth brush systems 310a to 310f may be independent of each other, and the shapes, numbers, and constituent materials of the first to sixth nodules 312a to 312f may be different. This is described in detail below.

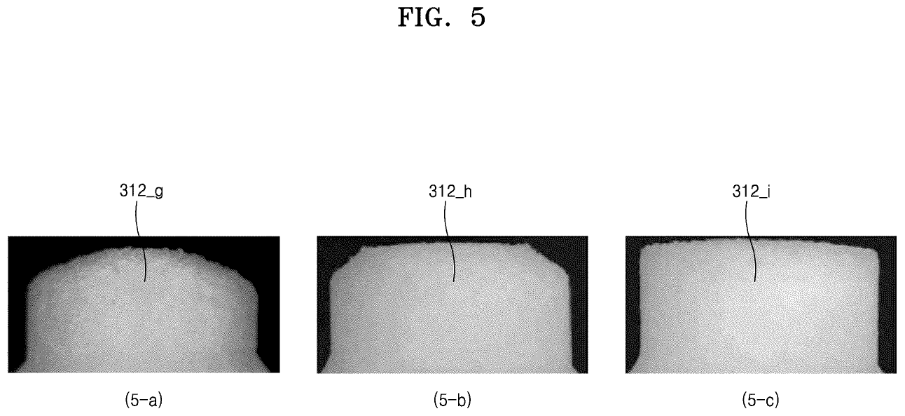

FIG. 5 shows examples of nodules of a wafer cleaning device according to some implementations. For convenience of description, in FIG. 5, a nodule in (5-a) is referred to as a first nodule 312_g, a nodule in (5-b) is referred to as a second nodule 312_h, and a nodule in (5-c) is referred to as a third nodule 312_i. Each of the first to third nodules 312_g to 312_i in (5-a), (5-b), and (5-c) may be an example of the first to sixth nodules 312a to 312f in FIG. 4. In other words, each of the first to sixth nodules 312a to 312f in FIG. 4 may include one of the first to third nodules 312_g to 312_i in FIG. 5.

In FIG. 5, the first nodule 312_g in (5-a) may have the bluntest corner compared to the second nodule 312_h in (5-b) and the third nodule 312_i in (5-c). Because the corner of the first nodule 312_g is relatively curved rather than sharp, the first nodule 312_g may have the least friction with a wafer when a body rotates, compare to the second nodule 312_h and the third nodule 312_i. Accordingly, when a region of the wafer, which is vulnerable to friction or has a relatively high number of contacts with a nodule, is cleaned, the first nodule 312_g may be used.

In FIG. 5, the corner of the second nodule 312_h in (5-b) may be sharper than the corner of the first nodule 312_g in (5-a) and blunter than the corner of the third nodule 312_i in (5-c). When the corner of the second nodule 312_h is sharp, the friction between the second nodule 312_h and the wafer may increase when the body rotates.

In FIG. 5, the third nodule 312_i in (5-c) may have the sharpest corner compared to the first nodule 312_g in (5-a) and the second nodule 312_h in (5-b). Because the corner of the third nodule 312_i is sharp, the third nodule 312_i may have the greatest friction with the wafer when the body rotates, compared to the first nodule 312_g and the second nodule 312_h. Accordingly, when a region of the wafer, which is resistant to friction or has a relatively small number of contacts with a nodule, is cleaned, the third nodule 312_i may be used.

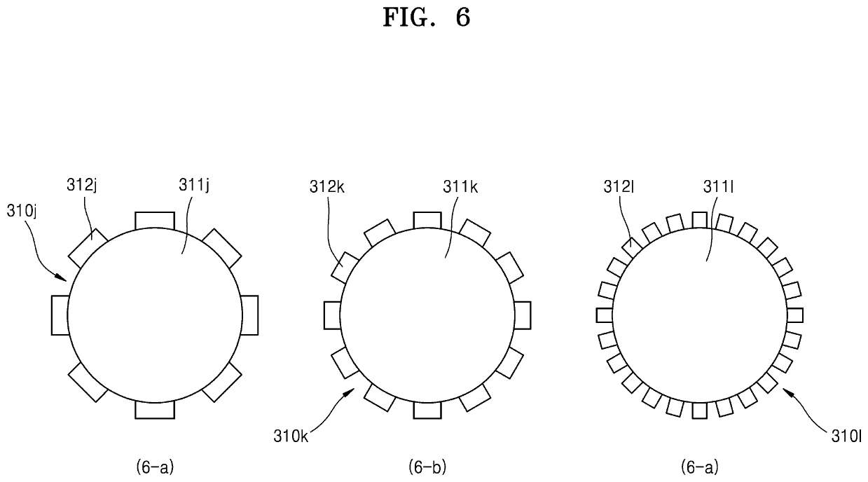

FIG. 6 shows cross-sections of examples of wafer cleaning devices according to some implementations. For convenience of description, in FIG. 6, a brush system in (6-a) is referred to as a first brush system 310j, a brush system in (6-b) is referred to as a second brush system 310k, and a brush system in (6-c) is referred to as a third brush system 310l. Each of the first brush system 310j, the second brush system 310k, and the third brush system 310l may be an example of the first to sixth brush systems 310a to 310f in FIG. 4. In other words, each of the first to sixth brush systems 310a to 310f in FIG. 4 may include one of the first to third brush systems 310j, 310k, and 310l in FIG. 6.

In FIG. 6, the first brush system 310j in (6-a) may include a first body 311j having a cylindrical shape and a plurality of first nodules 312j arranged on the outer surface of the first body 311j. The second brush system 310k in (6-b) may include a second body 311k having a cylindrical shape and a plurality of second nodules 312k arranged on the outer surface of the second body 311k. The third brush system 310l in (6-c) may include a third body 311l having a cylindrical shape and a plurality of third nodules 312l arranged on the outer surface of the third body 311l.

In FIG. 6, the first to third brush systems 310j, 310k, and 310l respectively shown in (6-a), (6-b), and (6-c) are substantially the same as or similar to each other, except for the number of nodules.

In FIG. 6, the first brush system 310j in (6-a) may have the least number of nodules compared to the second brush system 310k in (6-b) and the third brush system 310l in (6-c). When the least number of first nodules 312j are arranged on the outer surface of the first body 311j, the first brush system 310j may contact a wafer the least number of times when the first body 311j rotates, compared to the second brush system 310k and the third brush system 310l. Accordingly, the first brush system 310j may be used when a region of the wafer that is vulnerable to friction or has a relatively large number of contacts with nodules is cleaned.

In FIG. 6, the second brush system 310k in (6-b) may have more nodules than the first brush system 310j in (6-a) and fewer nodules than the third brush system 310l in (6-c). When the number of second nodules 312k increases, the number of contacts and the friction between the second brush system 310k and the wafer may increase when the second body 311k rotates.

According to some implementations, the size of the second nodules 312k may be smaller than the size of the first nodules 312j to arrange, on the outer surface of the second body 311k, a greater number of second nodules 312k than the first nodules 312j of the first brush module 310j.

In FIG. 6, the third brush system 310l in (6-c) may have the largest number of nodules compared to the first brush system 310j in (6-a) and the second brush system 310k in (6-b). When a largest number of nodules are arranged on the outer surface of the third body 311l, the third brush system 310l may contact the wafer the largest number of times when the third body 311l rotates, compared to the first brush module 310j and the second brush module 310k. Accordingly, the third brush system 310l may be used when a region of the wafer that is resistant to friction or has a relatively small number of contacts with nodules is cleaned.

According to some implementations, the size of the third brush system 310l may be smaller than the size of the second brush system 310k to arrange, on the outer surface of the third body 311l, a greater number of third nodules 312l than the second nodules 312k of the second brush system 310k.

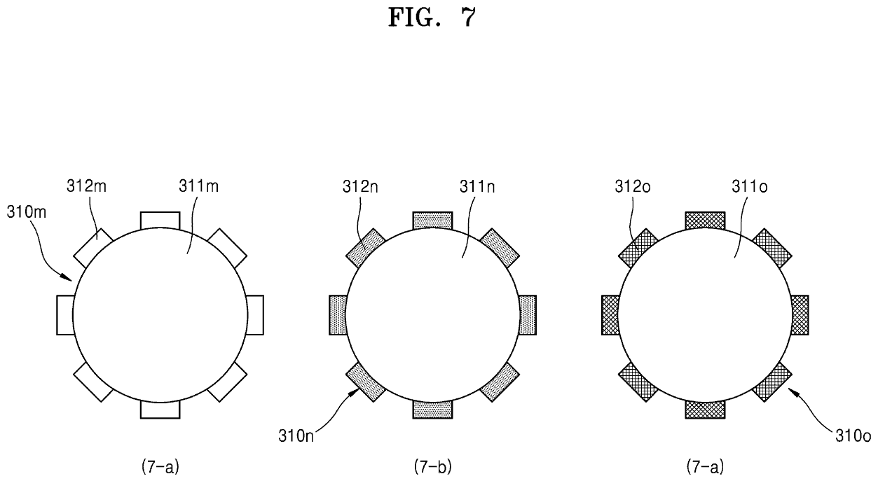

FIG. 7 shows cross-sections of examples of wafer cleaning devices according to some implementations. For convenience of description, in FIG. 7, a brush system in (7-a) is referred to as a first brush system 310m, a brush system in (7-b) is referred to as a second brush system 310n, and a brush system in (7-c) is referred to as a third brush module 3100. Each of the first brush system 310m, the second brush system 310n, and the third brush system 3100 may be an example of the first to sixth brush systems 310a to 310f in FIG. 4. In other words, each of the first to sixth brush systems 310a to 310f in FIG. 4 may include one of the first to third brush systems 310m, 310n, and 3100 in FIG. 7.

In FIG. 7, the first brush system 310m in (7-a) may include a first body 311m having a cylindrical shape and a plurality of first nodules 312m arranged on the outer surface of the first body 311m. The second brush system 310n in (7-b) may include a second body 311n having a cylindrical shape and a plurality of second nodules 312n arranged on the outer surface of the second body 311n. The third brush system 3100 in (7-c) may include a third body 3110 having a cylindrical shape and a plurality of third nodules 3120 arranged on the outer surface of the third body 3110.

The first to third brush systems 310m, 310n, and 3100 respectively shown in (7-a), (7-b), and (7-c) of FIG. 7 are substantially the same as or similar to each other, except for the materials of nodules.

In FIG. 7, the first nodules 312m in (7-a) may include the softest material compared to the second nodules 312n in (7-b) and the third nodules 3120 in (7-c). Here, “being soft” may mean having low hardness. When the first nodules 312m having the lowest hardness are arranged on the outer surface of the first body 311m, the first brush system 310m may have the least friction with a wafer when the first body 311m rotates, compared to the second brush system 310n and the third brush system 3100. Accordingly, the first brush system 310m may be used when a region of the wafer that is vulnerable to friction or has a relatively large number of contacts with nodules is cleaned.

In FIG. 7, the second nodules 312n in (7-b) may be harder than the first nodules 312m in (7-a) and may be softer than the third nodules 3120 in (7-c). Here, “being hard” may mean having high hardness. When the hardness of the second nodules 312n increases, the friction between the second brush system 310n and the wafer may increase when the second body 311n rotates.

In FIG. 7, the hardness of the third nodules 3120 in (7-c) may be highest compared to the first nodules 312m in (7-a) and the second nodules 312n in (7-b). When the third nodules 3120 having the highest hardness are arranged on the outer surface of the third body 3110, the third brush system 3100 may have the greatest friction with a wafer when the third body 3110 rotates, compared to the first brush system 310m and the second brush system 310n. Accordingly, the third brush system 3100 may be used when a region of the wafer that is resistant to friction or has a relatively small number of contacts with nodules is cleaned.

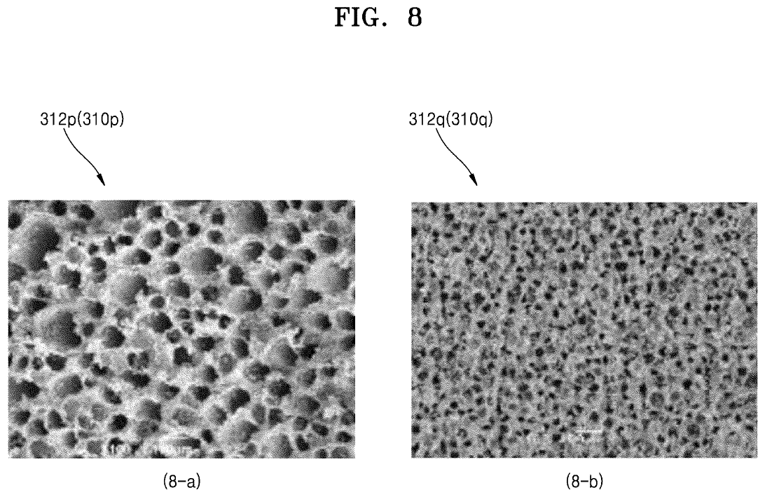

FIG. 8 shows enlarged views of examples of nodules of a wafer cleaning device according to some implementations. For convenience of description, in FIG. 8, a nodule in (8-a) is referred to as a first nodule 312p, and a nodule in (8-b) is referred to as a second nodule 312q. Each of the first nodule 312p and the second nodule 312q may be an example of the first to sixth nodules 312a to 312f in FIG. 4. In other words, each of the first to sixth nodules 312a to 312f in FIG. 4 may include one of the first and second nodules 312p and 312q in FIG. 8.

In FIG. 8, the first and second nodules 312p and 312q respectively shown in (8-a) and (8-b) are substantially the same as or similar to each other, except for the size of a pore.

In FIG. 8, the first nodule 312p in (8-a) may have a larger pore than the second nodule 312q in (8-b). When the size of a pore is large, the hardness of a nodule may decrease. When the first nodule 312p having low hardness is arranged on the outer surface of a body, a first brush system 310p may have low friction with a wafer when the body rotates, compared to a second brush system 310q. Accordingly, the first brush system 310p may be used when a region of the wafer that is vulnerable to friction or has a relatively large number of contacts with nodules is cleaned.

In FIG. 8, the second nodule 312q in (8-b) may have a smaller pore than the first nodule 312p in (8-a). When the size of a pore is small, the hardness of a nodule may increase. When the second nodule 312q having high hardness is arranged on the outer surface of a body, the second brush system 310q may have high friction with a wafer when the body rotates, compared to the first brush system 310p. Accordingly, the second brush system 310q may be used when a region of the wafer that is resistant to friction or has a relatively small number of contacts with nodules is cleaned.

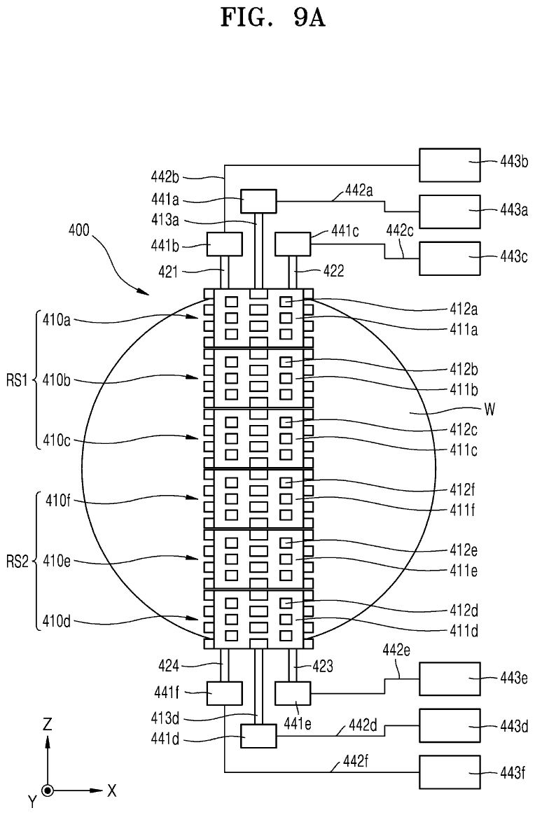

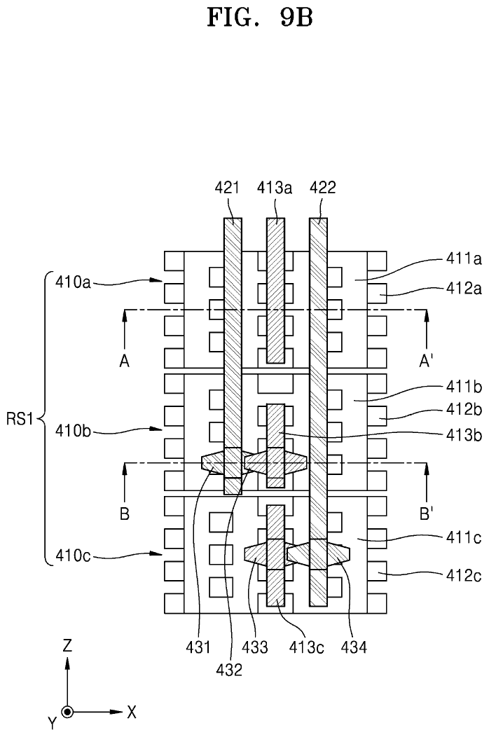

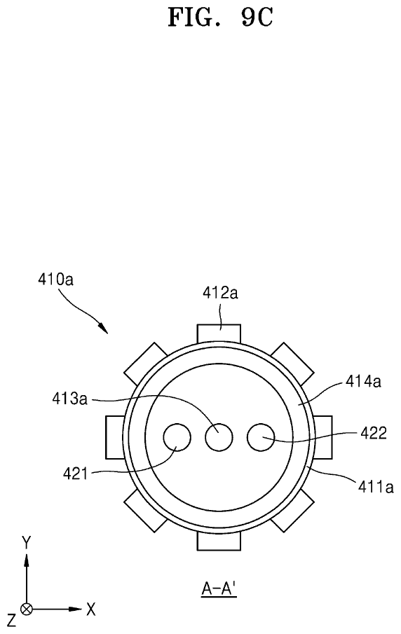

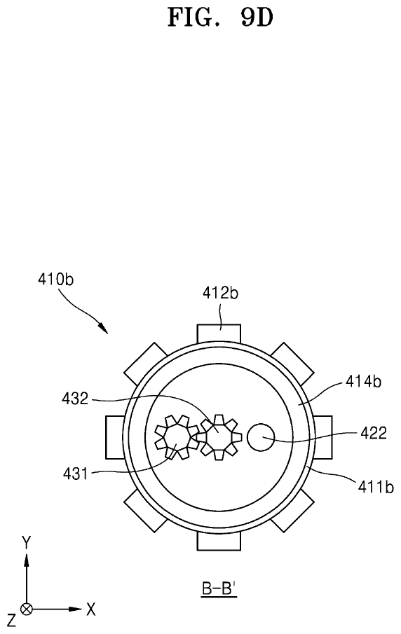

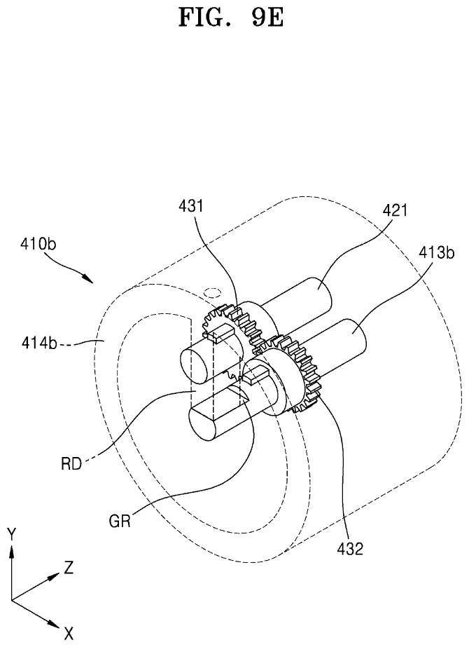

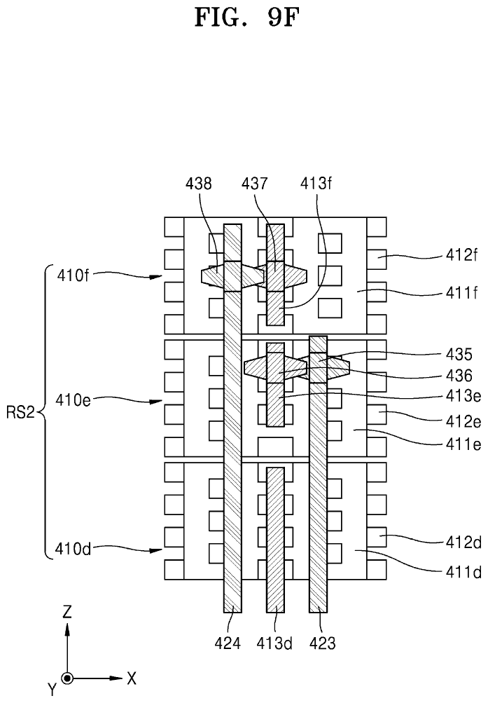

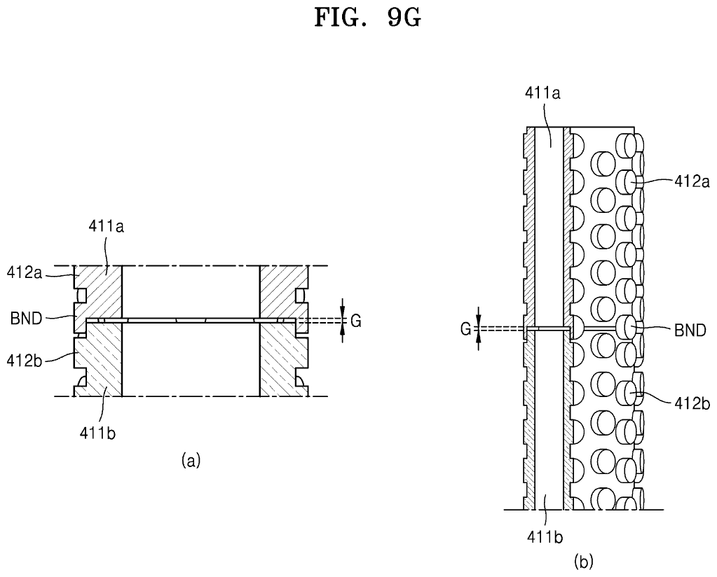

FIG. 9A is a plan view illustrating an example of a wafer cleaning device according to some implementations. In FIG. 9A, a wafer cleaning device 400 may include a first brush structure RS1 and a second brush structure RS2, which are arranged in a line in one direction, a plurality of driveshafts (e.g., 413a and 413d), a plurality of transmission shafts (e.g., 421, 422, 423, and 424), a plurality of actuators (e.g., 441a to 441f), and a plurality of controllers (e.g., 443a to 443f).

The first brush structure RS1 may include a first brush system 410a, a second brush system 410b, and a third brush system 410c, which are arranged in a line in the reverse vertical direction (the −Z direction). The second brush structure RS2 may include a fourth brush system 410d, a fifth brush system 410e, and a sixth brush system 410f, which are arranged in a line in the vertical direction (the Z direction).

In FIG. 9A, the first brush system 410a may include a first body 411a and a first nodule 412a. The second brush system 410b may include a second body 411b and a second nodule 412b. The third brush system 410c may include a third body 411c and a third nodule 412c. The fourth brush system 410d may include a fourth body 411d and a fourth nodule 412d. The fifth brush system 410c may include a fifth body 411e and a fifth nodule 412e. The sixth brush system 410f may include a sixth body 411f and a sixth nodule 412f.

In FIG. 9A, the first to sixth bodies 411a to 411f and the first to sixth nodules 412a to 412f are substantially the same as the first to sixth bodies 311a to 311f and the first to sixth nodules 312a to 312f in FIG. 4, and redundant descriptions made above with reference to FIG. 4 are omitted below.

In FIG. 9A, the driveshafts (413a and 413d), the transmission shafts (421 to 424), the actuators (441a to 441f), and the controllers (443a to 443f) are described in detail with reference to FIGS. 9B to 9G below.

FIG. 9B is a plan view illustrating an example of the first brush structure RS1 in FIG. 9A according to some implementations. FIG. 9C is a cross-sectional view taken along line A-A′ in FIG. 9B according to some implementations. FIG. 9D is a cross-sectional view taken along line B-B′ in FIG. 9B according to some implementations.

FIG. 9B illustrates the first brush structure RS1 including the first to third brush systems 410a to 410c arranged in a line in the vertical direction (the Z direction). The first brush system 410a may further include a first driveshaft 413a configured to rotate the first body 411a in one direction. The second brush system 410b may further include a second driveshaft 413b configured to rotate the second body 411b in one direction. The third brush system 410c may further include a third driveshaft 413c configured to rotate the third body 411c in one direction.

The first driveshaft 413a may be located in a central portion of the first body 411a in a horizontal view. In a cross-section that is perpendicular to the first horizontal direction (the X direction and the second horizontal direction (the Y direction), the first driveshaft 413a may be at the center of the first body 411a. When the first driveshaft 413a rotates around an axis parallel with the vertical direction (the Z direction), the first driveshaft 413a and the first body 411a may integrally rotate.

Similarly, the second driveshaft 413b may be located in a central portion of the second body 411b in a horizontal view. In a cross-section that is perpendicular to the first horizontal direction (the X direction and the second horizontal direction (the Y direction), the second driveshaft 413b may be at the center of the second body 411b. When the second driveshaft 413b rotates around an axis parallel with the vertical direction (the Z direction), the second driveshaft 413b and the second body 411b may integrally rotate.

Similarly, the third driveshaft 413c may be located in a central portion of the third body 411c in a horizontal view. In a cross-section that is perpendicular to the first horizontal direction (the X direction and the second horizontal direction (the Y direction), the third driveshaft 413c may be at the center of the third body 411c. When the third driveshaft 413c rotates around an axis parallel with the vertical direction (the Z direction), the third driveshaft 413c and the third body 411c may integrally rotate.

The first driveshaft 413a may be located only inside the first body 411a and may not overlap the second body 411b or the third body 411c. The second driveshaft 413b may be located only inside the second body 411b and may not overlap the first body 411a or the third body 411c. The third driveshaft 413c may be located only inside the third body 411c and may not overlap the first body 411a or the second body 411b.

A first transmission shaft 421 may extend from the outside of the first brush structure RS1 through the first body 411a to overlap at least a portion of the second body 411b. As shown in FIG. 9C, in a cross-section that is perpendicular to the first horizontal direction (the X direction and the second horizontal direction (the Y direction), the first transmission shaft 421 may be at one side of the first driveshaft 413a or the second driveshaft 413b.

The wafer cleaning device 400 may further include a first connector 431, which is fastened to the first transmission shaft 421 to surround the first transmission shaft 421, and a second connector 432, which is fastened to the second driveshaft 413b to surround the second driveshaft 413b. In this case, the first connector 431 may be configured to be fastened to the first transmission shaft 421 and to integrally rotate with the first transmission shaft 421, and the second connector 432 may be configured to be fastened to a second transmission shaft 422 and to integrally rotate with the second transmission shaft 422. For example, the first connector 431 and the second connector 432 may be gear.

According to some implementations, the first connector 431 and the second connector 432 may engage and rotate with each other to exchange power with each other.

The second transmission shaft 422 may extend from the outside of the first brush structure RS1 through the first body 411a and the second body 411b to overlap at least a portion of the third body 411c. As shown in FIG. 9C, in a cross-section that is perpendicular to the first horizontal direction (the X direction and the second horizontal direction (the Y direction), the second transmission shaft 422 may be at one side of the first driveshaft 413a or the second driveshaft 413b. In this case, the first transmission shaft 421 and the second transmission shaft 422 may be separated from each other with the first driveshaft 413a therebetween. However, positional relations among the first transmission shaft 421, the second transmission shaft 422, and the first to third driveshafts 413a to 413c is not limited to those shown in FIG. 9B.

The wafer cleaning device 400 may further include a third connector 433, which is fastened to the third driveshaft 413c to surround the third driveshaft 413c, and a fourth connector 434, which is fastened to the second transmission shaft 422 to surround the second transmission shaft 422. In this case, the third connector 433 may be configured to be fastened to the third driveshaft 413c and to integrally rotate with the third driveshaft 413c, and the fourth connector 434 may be configured to be fastened to the second transmission shaft 422 and to integrally rotate with the second transmission shaft 422. For example, the third connector 433 and the fourth connector 434 may be gear.

According to some implementations, the first to third driveshafts 413a to 413c and the first and second transmission shafts 421 and 422 may each have, but not limited to, a cylindrical shape.

According to some implementations, the first brush system 410a, the second brush system 410b, and the third brush system 410c of the first brush structure RS1 may be configured to independently rotate with the vertical direction (the Z direction) as a rotation axis. The rotation mechanism of the first to third brush systems 410a to 410c are described in detail below.

The first driveshaft 413a may extend from the outside of the first body 411a and overlap with at least a portion of the first body 411a. The first driveshaft 413a may be connected to a first actuator 441a. The first actuator 441a may be electrically connected to a first controller 443a through a first wire 442a. The first actuator 441a may be configured to receive a signal of the first controller 443a and cylindrically rotate the first driveshaft 413a in one direction.

The first transmission shaft 421 may extend from the outside of the first body 411a completely through the first body 411a and overlap at least a portion of the second body 411b. The first transmission shaft 421 may be connected to a second actuator 441b. The second actuator 441b electrically connected to a second controller 443b through a second wire 442b. The second actuator 441b may be configured to receive a signal of the second controller 443b and cylindrically rotate the first transmission shaft 421 in one direction.

The second transmission shaft 422 may extend from the outside of the first body 411a completely through the first body 411a and the second body 411b and overlap at least a portion of the third body 411c. The second transmission shaft 422 may be connected to a third actuator 441c. The third actuator 441c may be electrically connected to a third controller 443c through a third wire 442c. The third actuator 441c may be configured to receive a signal of the third controller 443c and cylindrically rotate the second transmission shaft 422 in one direction.

According to some implementations, the first driveshaft 413a may be directly connected to the first actuator 441a to rotate, but the second driveshaft 413b and the third driveshaft 413c may not be directly connected to an actuator.

The first controller 443a may send an electrical signal to the first actuator 441a to cylindrically rotate the first driveshaft 413a. The first actuator 441a that has received the electrical signal from the first controller 443a may cylindrically rotate the first driveshaft 413a. Accordingly, the first body 411a fastened to and integrally rotating with the first driveshaft 413a may rotate under control by the first controller 443a.

The second controller 443b may send an electrical signal to the second actuator 441b to cylindrically rotate the first transmission shaft 421. The second actuator 441b that has received the electrical signal from the second controller 443b may cylindrically rotate the first transmission shaft 421. The first connector 431 fastened to the first transmission shaft 421 may be configured to engage and rotate with the second connector 432 fastened to the second driveshaft 413b. In other words, the second connector 432 may receive torque from the first connector 431. The second driveshaft 413b may receive the torque of the first transmission shaft 421 through the first connector 431 and the second connector 432 and thus cylindrically rotate. Accordingly, the second body 411b fastened to and integrally rotating with the second driveshaft 413b may rotate under control by the second controller 443b.

The third controller 443c may send an electrical signal to the third actuator 441c to cylindrically rotate the second transmission shaft 422. The third actuator 441c that has received the electrical signal from the third controller 443c may cylindrically rotate the second transmission shaft 422. The fourth connector 434 fastened to the second transmission shaft 422 may be configured to engage and rotate with the third connector 433 fastened to the third driveshaft 413c. In other words, the third connector 433 may receive torque from the fourth connector 434. The third driveshaft 413c may receive the torque of the second transmission shaft 422 through the third connector 433 and the fourth connector 434 and thus cylindrically rotate. Accordingly, the third body 411c fastened to and integrally rotating with the third driveshaft 413c may rotate under control by the third controller 443c.

Because the first to third brush systems 410a to 410c are respectively rotated by separate actuators, the first to third brush systems 410a to 410c may independently rotate at different speeds.

For example, referring to FIG. 9A, when the wafer W rotates around the rotation axis parallel with the second horizontal direction (the Y direction), the linear velocity of an outer portion of the wafer W in the radial direction may be greater than that of a central portion of the wafer W. Accordingly, when the first to third brush systems 410a to 410c rotate at the same speed, the friction between the first brush system 410a and the outer portion of the wafer W in the radial direction may be greater than the friction between the third brush system 410c and the central portion of the wafer W.

Accordingly, to uniformly clean the entire area of the wafer W, the third brush system 410c near the central portion of the wafer W may be rotated at a relatively high speed and the first brush system 410a near the outer portion of the wafer W may be rotated at a relatively low speed. In this case, the second brush system 410b may be rotated at an intermediate speed between the speed of the first brush system 410a and the speed of the third brush system 410c.

According to some implementations, the first to third actuators 441a to 441c may include a motor generating torque. However, the present disclosure is not limited thereto. The first to third actuators 441a to 441c may include, without limitation, any configuration that cylindrically rotates the first driveshaft 413a and the first and second transmission shafts 421 and 422.

In some implementations, the first to third controllers 443a to 443c may be implemented by hardware, firmware, software, or a combination thereof. For example, the first to third controllers 443a to 443c may include a computing device, such as a workstation computer, a desktop computer, a laptop computer, or a tablet computer. The first to third controllers 443a to 443c may include a simple controller, a microprocessor, a complex processor such as a central processing unit (CPU) or a graphics processing unit (GPU), a processor configured by software, or dedicated hardware or firmware. For example, the first to third controllers 443a to 443c may include a general-use computer or an application-specific hardware component, such as a digital signal processor (DSP), a field programmable gate array (FPGA), or an application-specific integrated circuit (ASIC).

In some implementations, the operations of the first to third controllers 443a to 443c may be embodied as instructions, which are stored in a machine-readable medium and may be read and executed by at least one processor. Here, the machine-readable medium may include a mechanism for storing and/or transmitting information in a form readable by a machine (e.g., a computing device). Examples of the machine-readable medium may include read-only memory (ROM), random-access memory (RAM), magnetic disk storage media, optical storage media, flash memory devices, electrical, optical or acoustic or other types of wave signals (e.g., carriers, infrared signals, digital signals, etc.), and other signals.

The first to third controllers 443a to 443c may be embodied as firmware, software, routines, and/or instructions for operating the first to third actuators 441a to 441c. For example, the first to third controllers 443a to 443c may receive data for feedback and generate signals for operating the first to third actuators 441a to 441c and may be implemented by software performing a certain operation.

The wafer cleaning device 400 may further include a fourth driveshaft 413d, third and fourth transmission shafts 423 and 424, fourth to sixth actuators 441d to 441f, fourth to sixth wires 442d to 442f, and fourth to sixth controllers 443d to 443f. These elements and the rotation mechanism of the second brush structure RS2 are described with reference to FIG. 9F below.

A first housing 414a in FIG. 9C and a second housing 414b in FIG. 9D are described in detail below.

FIG. 9E is a perspective view illustrating an example of a part of the wafer cleaning device of FIG. 9A according to some implementations. In FIGS. 9D and 9E, the second brush system 410b may include the second housing 414b having a hollow accommodating therein the second driveshaft 413b, the first transmission shaft 421, and the second transmission shaft 422. Similarly, as shown in FIG. 9C, the first brush system 410a may include the first housing 414a having a hollow accommodating therein the first driveshaft 413a, the first transmission shaft 421, and the second transmission shaft 422. The third brush system 410c (see FIG. 9B) may also include a housing having a hollow accommodating therein the third driveshaft 413c (see FIG. 9B) and the second transmission shaft 422 (see FIG. 9B).

As shown in FIG. 9C, the outer surface of the first housing 414a may be fastened to and in contact with the first body 411a. Accordingly, as the first housing 414a rotates, the first body 411a may also rotate together with the first housing 414a.

Similarly, as shown in FIG. 9D, the outer surface of the second housing 414b may be fastened to and in contact with the second body 411b. Accordingly, as the second housing 414b rotates, the second body 411b may also rotate together with the second housing 414b.

The outer surface of the third housing may be fastened to and in contact with the third body 411c (see FIG. 9B). Accordingly, as the third housing rotates, the third body 411c (see FIG. 9B) may also rotate together with the third housing.

The second housing 414b having a tube shape may include a rod RD extending toward the second driveshaft 413b. In this case, the second driveshaft 413b may have a groove GR which is in close contact with so that the second driveshaft 413b integrally rotates with the rod RD.

For example, the rod RD may have a cuboid shape having a rectangular end section, and the groove GR in close contact with the rod RD may also have a rectangular cross-section. The groove GR may refer to a quadrangle-shaped portion in the cylindrical shape of the second driveshaft 413b.

According to some implementations, the top surface of the groove GR may be in full contact with the bottom surface of the rod RD. Because the groove GR is in full close contact with the rod RD, the rod RD may rotate around the rotation axis of the second driveshaft 413b as the second driveshaft 413b cylindrically rotates. The rod RD may be configured to deliver the torque of the second driveshaft 413b to the second housing 414b. Because the road RD is in full close contact with the groove GR of the second driveshaft 413b, the second housing 414b integrally formed with the rod RD may cylindrically rotate when the second driveshaft 413b cylindrically rotates.

Only the case where the rod RD of the second housing 414b is in close contact with the second driveshaft 413b and the second housing 414b integrally rotates with the second driveshaft 413b has been illustrated and described. However, the description of power transmission between the second housing 414b and the second driveshaft 413b may also be applied to the power transmission between the first housing 414a and the first driveshaft 413a and the power transmission between the third housing and the third driveshaft 413c.

FIG. 9F is a plan view illustrating an example of the second brush structure RS2 in FIG. 9A according to some implementations. In FIG. 9F, the second brush structure RS2 including the fourth to sixth brush systems 410d to 410f arranged in a line in the vertical direction (the Z direction).

In FIG. 9F, the second brush structure RS2 and the first brush structure RS1 are symmetrical with respect to a virtual boundary line in the first horizontal direction (the X direction) between the first brush structure RS1 and the second brush structure RS2 and have substantially the same operating principle and configuration. Accordingly, redundant descriptions among the descriptions of the first brush structure RS1 are omitted below.

In FIG. 9F, the fourth brush system 410d may further include a fourth driveshaft 413d configured to rotate the fourth body 411d in one direction. The fifth brush system 410e may further include a fifth driveshaft 413e configured to rotate the fifth body 411e in one direction. The sixth brush system 410f may further include a sixth driveshaft 413f configured to rotate the sixth body 411f in one direction.

In a cross-section that is perpendicular to the first horizontal direction (the X direction and the second horizontal direction (the Y direction), the fourth driveshaft 413d may be at the center of the fourth body 411d. When the fourth driveshaft 413d rotates around an axis parallel with the vertical direction (the Z direction), the fourth driveshaft 413d and the fourth body 411d may integrally rotate.

Similarly, in a cross-section that is perpendicular to the first horizontal direction (the X direction and the second horizontal direction (the Y direction), the fifth driveshaft 413e may be at the center of the fifth body 411e. When the fifth driveshaft 413e rotates around an axis parallel with the vertical direction (the Z direction), the fifth driveshaft 413e and the fifth body 411e may integrally rotate.

Similarly, in a cross-section that is perpendicular to the first horizontal direction (the X direction and the second horizontal direction (the Y direction), the sixth driveshaft 413f may be at the center of the sixth body 411f. When the sixth driveshaft 413f rotates around an axis parallel with the vertical direction (the Z direction), the sixth driveshaft 413f and the sixth body 411f may integrally rotate.

The descriptions of the first brush system 410a may be applied to the fourth brush system 410d, the descriptions of the second brush system 410b may be applied to the fifth brush system 410c, and the descriptions of the third brush system 410c may be applied to the sixth brush system 410f. Accordingly, the detailed descriptions thereof are omitted below.

The wafer cleaning device 400 may further include a fifth connector 435, which is fastened to the third transmission shaft 423 to surround the third transmission shaft 423, and a sixth connector 436, which is fastened to the fifth driveshaft 413e to surround the fifth driveshaft 413c. In this case, the fifth connector 435 may be configured to be fastened to the third transmission shaft 423 and to integrally rotate with the third transmission shaft 423, and the sixth connector 436 may be configured to be fastened to the fifth driveshaft 413c and to integrally rotate with the fifth driveshaft 413c. For example, the fifth connector 435 and the sixth connector 436 may be gear.

The wafer cleaning device 400 may further include a seventh connector 437, which is fastened to the sixth driveshaft 413f to surround the sixth driveshaft 413f, and an eighth connector 438, which is fastened to the fourth transmission shaft 424 to surround the fourth transmission shaft 424. In this case, the seventh connector 437 may be configured to be fastened to the sixth driveshaft 413f and to integrally rotate with the sixth driveshaft 413f, and the eighth connector 438 may be configured to be fastened to the fourth transmission shaft 424 and to integrally rotate with the fourth transmission shaft 424. For example, the seventh connector 437 and the eighth connector 438 may be gear.

According to some implementations, the fourth sixth driveshafts 413d to 413f and the third and fourth transmission shafts 423 and 424 may have, but are not limited to, a cylindrical shape.

The fourth driveshaft 413d may be connected to the fourth actuator 441d. The fourth actuator 441d may be electrically connected to the fourth controller 443d through the fourth wire 442d (in FIG. 9A). The fourth actuator 441d may be configured to receive a signal of the fourth controller 443d and cylindrically rotate the fourth driveshaft 413d in one direction.

The third transmission shaft 423 may be connected to the fifth actuator 441e. The fifth actuator 441e may be electrically connected to the fifth controller 443e through the fifth wire 442c (in FIG. 9A). The fifth actuator 441e may be configured to receive a signal of the fifth controller 443c and cylindrically rotate the third transmission shaft 423 in one direction.

The fourth transmission shaft 424 may be connected to the sixth actuator 441f. The sixth actuator 441f may be electrically connected to the sixth controller 443f through the sixth wire 442f (in FIG. 9A). The sixth actuator 441f may be configured to receive a signal of the sixth controller 443f and cylindrically rotate the fourth transmission shaft 424 in one direction.

According to some implementations, the fourth driveshaft 413d may be directly connected to the fourth actuator 441d to rotate, but the fifth driveshaft 413e and the sixth driveshaft 413f may not be directly connected to an actuator.

The function of the fourth controller 443d may be similar to that of the first controller 443a. The function of the fifth controller 443e may be similar to that of the second controller 443b. The function of the sixth controller 443f may be similar to that of the third controller 443c. Thus, detailed descriptions of the fourth to sixth controllers 443d to 443f are omitted.

Because the fourth to sixth brush systems 410d to 410f are respectively rotated by separate actuators, the fourth to sixth brush systems 410d to 410f may independently rotate at different speeds.

FIG. 9G shows a cross-sectional view and a perspective view of an example of a part of the first brush structure RS1 in FIG. 9A according to some implementations. In FIG. 9G, a plurality of first nodules 412a may be formed on the outer portion of the first body 411a, and a plurality of second nodules 412b may be formed on the outer portion of the second body 411b.

A gap G may be formed between a central portion of the first body 411a in a radial direction perpendicular to a direction in which the first body 411a and the second body 411b are arranged in a line and a central portion of the second body 411b in the radial direction. The central portion of the first body 411a may be separated from the central portion of the second body 411b by the gap G. Because of the gap G between the central portion of the first body 411a and the central portion of the second body 411b, the first brush module 410a may be driven independently of the second brush module 410b.

According to some implementations, the first brush system 410a may further include a boundary nodule BND, which is on the outer portion of the first body 411a in the radial direction and blocks the gap G. As the first brush system 410a includes the boundary nodule BND blocking the gap G, a gap in a cleaned region may be prevented from occurring because a nodule is not arranged between the first body 411a and the second body 411b. The boundary nodule BND may overlap at least a portion of the first body 411a and at least a portion of the second body 411b in the radial direction. Here, the radial direction may be based on a circle corresponding to the cross-section of a cylindrical body.

Although only the boundary nodule BND blocking the gap G between the first body 411a and the second body 411b is described, the wafer cleaning device 400 may also include a boundary nodule blocking a gap between the second body 411b and the third body 411c, a boundary nodule blocking a gap between the third body 411c and the fourth body 411d, a boundary nodule blocking a gap between the fourth body 411d and the fifth body 411e, and a boundary nodule blocking a gap between the fifth body 411e and the sixth body 411f.

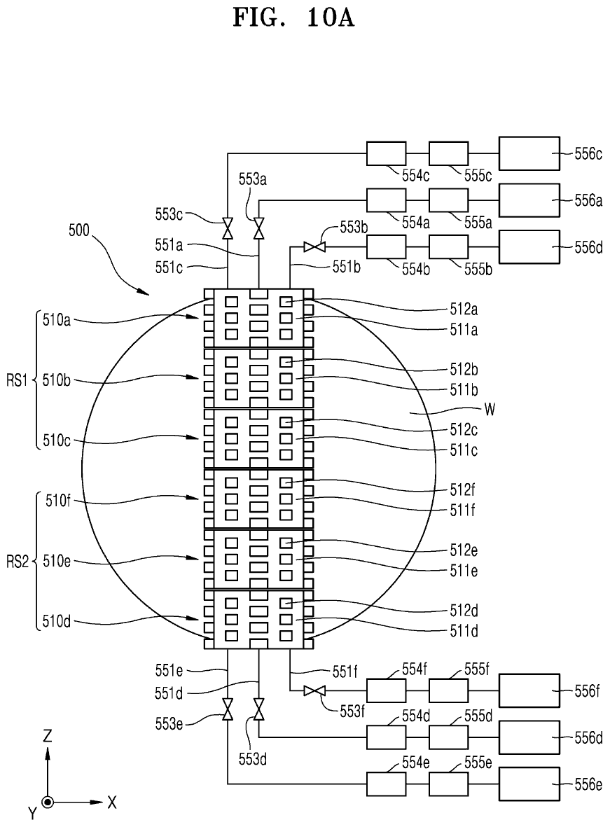

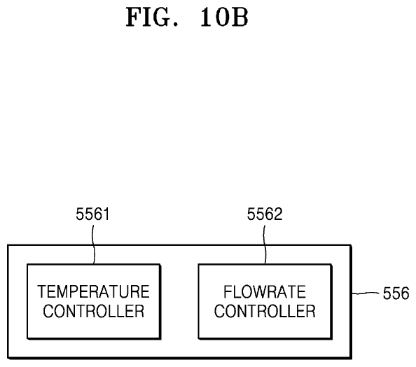

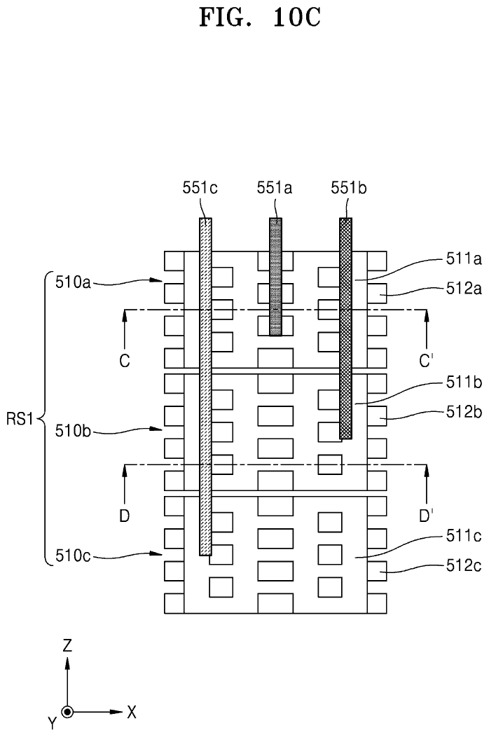

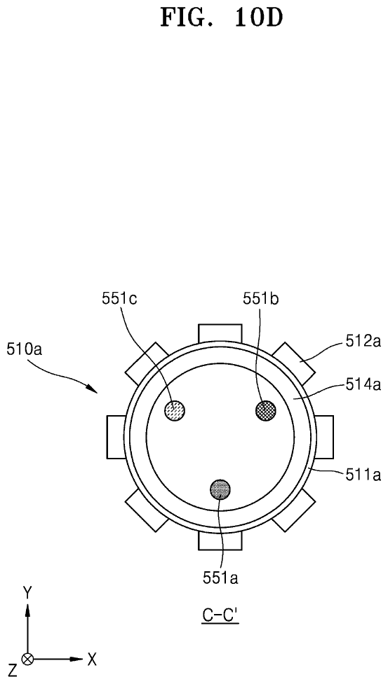

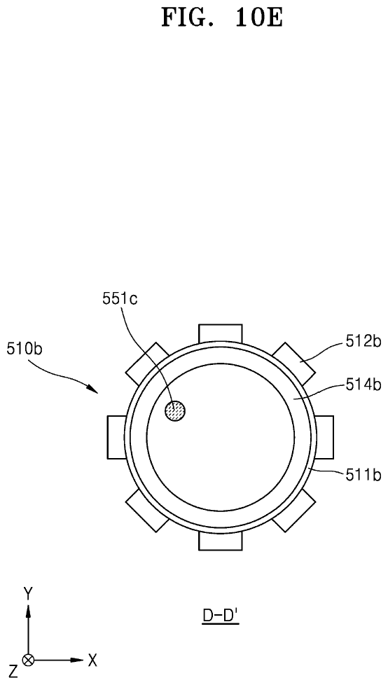

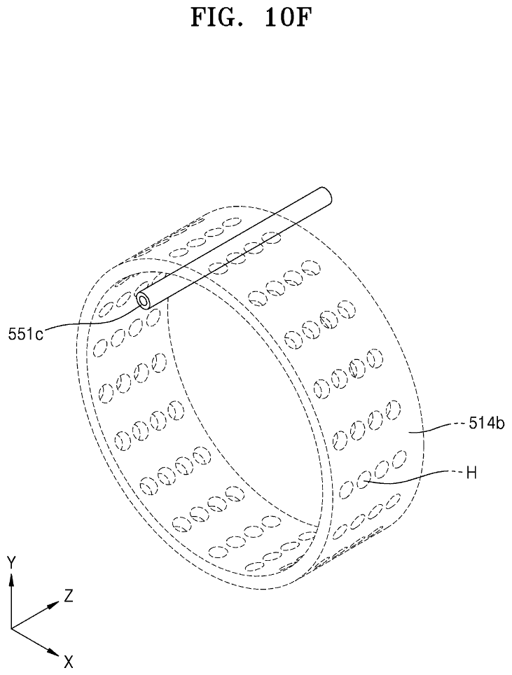

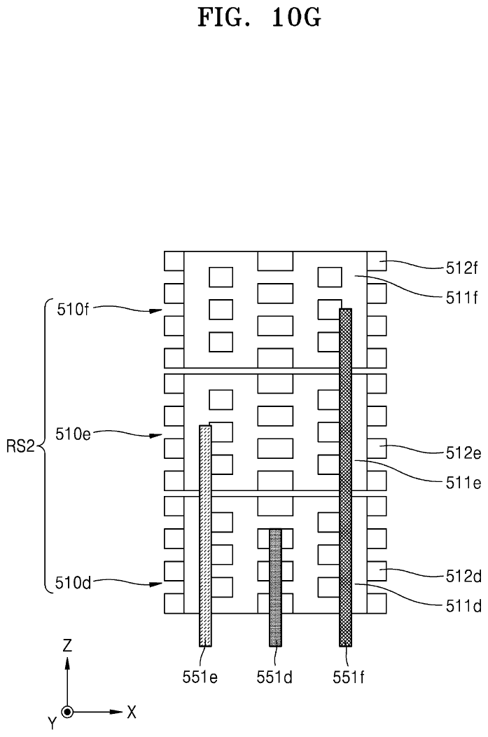

FIG. 10A is a plan view illustrating an example of a wafer cleaning device according to some implementations. FIG. 10B is a diagram illustrating an example of a controller in FIG. 10A according to some implementations.

In FIGS. 10A and 10B, a wafer cleaning device 500 may include a first brush structure RS1 and a second brush structure RS2, which are arranged in a line in one direction, a plurality of fluid supply pipes (e.g., 551a to 551f), a plurality of valves (e.g., 553a to 553f), a plurality of thermoregulators (e.g., 554a to 554f), a plurality of fluid accommodating parts (e.g., 555a to 555f), and a plurality of controllers (e.g., 556a to 556f).

The first brush structure RS1 may include a first brush system 510a, a second brush system 510b, and a third brush system 510c, which are arranged in a line in the reverse vertical direction (the −Z direction). The second brush structure RS2 may include a fourth brush system 510d, a fifth brush system 510e, and a sixth brush system 510f, which are arranged in a line in the vertical direction (the Z direction).

The first brush system 510a may include a first body 511a and a first nodule 512a. The second brush system 510b may include a second body 511b and a second nodule 512b. The third brush system 510c may include a third body 511c and a third nodule 512c. The fourth brush system 510d may include a fourth body 511d and a fourth nodule 512d. The fifth brush system 510c may include a fifth body 511e and a fifth nodule 512c. The sixth brush system 510f may include a sixth body 511f and a sixth nodule 512f.

The first to sixth bodies 511a to 511f and the first to sixth nodules 512a to 512f in FIG. 9A are substantially the same as the first to sixth bodies 311a to 311f and the first to sixth nodules 312a to 312f in FIG. 4, and redundant descriptions made above with reference to FIG. 4 are omitted below.

In FIG. 10B, a controller 556 may include a temperature controller 5561 and a flowrate controller 5562.

According to some implementations, the wafer cleaning device 500 may include a plurality of valves (553a to 553f), a plurality of thermoregulators (554a to 554f), a plurality of fluid accommodating parts (555a to 555f), and a plurality of controllers (556a to 556f).

The fluid supply pipes (551a to 551f), the valves (553a to 553f), the thermoregulators (554a to 554f), the fluid accommodating parts (555a to 555f), and the controllers (556a to 556f) are described in detail with reference to FIGS. 10C to 10E below.

FIG. 10C is a plan view illustrating an example of the first brush structure RS1 in FIG. 10A according to some implementations. FIG. 10D is a cross-sectional view taken along line C-C′ in FIG. 10C according to some implementations. FIG. 10E is a cross-sectional view taken along line D-D′ in FIG. 10C according to some implementations. FIG. 10F is a perspective view of a part of the first brush structure RS1 in FIG. 10A according to some implementations.

In FIGS. 10C to 10E, the first brush structure RS1 may include the first to third brush systems 510a to 510c, which are arranged in a line in the reverse vertical direction (the −Z direction).

The first brush system 510a may further include a first fluid supply pipe 551a configured to eject a first fluid to the first body 511a from inside the first body 511a. The second brush system 510b may further include a second fluid supply pipe 551b configured to eject a second fluid to the second body 511b from inside the second body 511b. The third brush system 510c may further include a third fluid supply pipe 551c configured to eject a third fluid to the third body 511c from inside the third body 511c. Here, the first fluid, the second fluid, and the second fluid may be of different types according to some implementations.

The first fluid supply pipe 551a may be positioned in a central portion of the first body 511a in a horizontal view. However, the position of the first fluid supply pipe 551a is just an example. According to some implementations, the first fluid supply pipe 551a may be positioned in an outer portion of the first body 511a.

The second fluid supply pipe 551b may be positioned in an outer portion of the second body 511b in a horizontal view. However, the position of the second fluid supply pipe 551b is just an example. According to some implementations, the second fluid supply pipe 551b may be positioned in a central portion of the second body 511b.

The third fluid supply pipe 551c may be positioned in an outer portion of the third body 511c in a horizontal view. However, the position of the third fluid supply pipe 551c is just an example. According to some implementations, the third fluid supply pipe 551c may be positioned in a central portion of the third body 511c.

According to some implementations, an end of the first fluid supply pipe 551a may be inside the first body 511a. Here, the end of the first fluid supply pipe 551a may refer to an ejection hole through which the first fluid is ejected from the first fluid supply pipe 551a. According to some implementations, a nozzle may be installed in the end of the first fluid supply pipe 551a.

According to some implementations, the second fluid supply pipe 551b may pass through the first body 511a, and an end of the second fluid supply pipe 551b may be inside the second body 511b. The third fluid supply pipe 551c may pass through the first body 511a and the second body 511b, and an end of the third fluid supply pipe 551c may be inside the third body 511c. Here, the end of the second fluid supply pipe 551b may refer to an ejection hole through which the second fluid is ejected from the second fluid supply pipe 551b, and the end of the third fluid supply pipe 551c may refer to an ejection hole through which the third fluid is ejected from the third fluid supply pipe 551c. According to some implementations, a nozzle may be installed in each of the end of the second fluid supply pipe 551b and the end of the third fluid supply pipe 551c.

The first fluid supply pipe 551a may not overlap either the second body 511b or the third body 511c in the second horizontal direction (the Y direction). The second fluid supply pipe 551b may not overlap the third body 511c in the second horizontal direction (the Y direction). However, the third fluid supply pipe 551c may overlap all the first body 511a and the second body 511b.

According to some implementations, pores may be formed in the first to third bodies 511a to 511c and the first to third nodules 512a to 512c, as described above with reference to FIG. 8. Accordingly, when the first to third fluid supply pipes 551a, 551b, and 551c respectively spray fluids to the first to third bodies 511a to 511c, fluids may escape through the pores and may be sprayed onto the wafer W to be cleaned.

According to some implementations, the first brush system 510a, the second brush system 510b, and the third brush system 510c of the first brush structure RS1 may be configured to independently spray fluids to the wafer W. The fluid spray mechanism of the first to third brush systems 510a to 510c is described in detail below.

The first fluid supply pipe 551a may extend from outside the first body 511a and overlap at least a portion of the first body 511a. The first fluid supply pipe 551a may be connected to a first valve 553a, a first thermoregulator 554a, a first fluid accommodating part 555a, and a first controller 556a.

As described above, one end of the first fluid supply pipe 551a may be inside the first body 511a. The opposite end of the first fluid supply pipe 551a may be connected to the first fluid accommodating part 555a, and the first valve 553a opening and closing the flow of a fluid may be installed in the first fluid supply pipe 551a. Although it is illustrated that the first valve 553a is installed in the first fluid supply pipe 551a to be adjacent to the first brush module structure RS1, the first valve 553a may be adjacent to the first fluid accommodating part 555a according to some implementations.

For example, the first fluid supply pipe 551a may have a pipe shape. The first fluid accommodating part 555a may include a storage tank having a space accommodating the first fluid.

According to some implementations, the first valve 553a may be installed in the first fluid supply pipe 551a and configured to adjust the flow speed and rate of the first fluid flowing through the first fluid supply pipe 551a.

According to some implementations, the first thermoregulator 554a may be installed in the first fluid supply pipe 551a and configured to adjust the temperature of the first fluid flowing through the first fluid supply pipe 551a. Although it is illustrated that the first thermoregulator 554a is installed in the first fluid supply pipe 551a to be adjacent to the first fluid accommodating part 555a, the first thermoregulator 554a may be adjacent to the first brush module structure RS1 according to some implementations.

According to some implementations, the first thermoregulator 554a may include a heater or a cooler.

In FIG. 10B, the controller 556 may include the temperature controller 5561 and the flowrate controller 5562. The temperature controller 5561 of each of the first to third controllers 556a to 556c (see FIG. 10A) may be electrically connected to one of first to third thermoregulators 554a to 554c and configured to exchange electrical signals for adjusting the temperature of a fluid with one of the first to third thermoregulators 554a to 554c. The flowrate controller 5562 of each of the first to third controllers 556a to 556c (see FIG. 10A) may be electrically connected to one of first to third valves 553a to 553c and configured to exchange electrical signals for adjusting the flowrate of a fluid with one of the first to third valves 553a to 553c.

In FIG. 10C, the second fluid supply pipe 551b may extend from outside the first body 511a through the first body 511a and overlap at least a portion of the second body 511b. The second fluid supply pipe 551b may be connected to the second valve 553b, the second thermoregulator 554b, the second fluid accommodating part 555b, and the second controller 556b. The third fluid supply pipe 551c may extend from outside the first body 511a through the first body 511a and the second body 511b and overlap at least a portion of the third body 511c. The third fluid supply pipe 551c may be connected to the third valve 553c, the third thermoregulator 554c, the third fluid accommodating part 555c, and the third controller 556c.

As described above, one end of the second fluid supply pipe 551b may be inside the second body 511b, and one end of the third fluid supply pipe 551c may be inside the third body 511c. The opposite end of the second fluid supply pipe 551b may be connected to the second fluid accommodating part 555b, and the second valve 553b opening and closing the flow of a fluid may be installed in the second fluid supply pipe 551b. The opposite end of the third fluid supply pipe 551c may be connected to the third fluid accommodating part 555c, and the third valve 553c opening and closing the flow of a fluid may be installed in the third fluid supply pipe 551c. Each of the second and third valves 553b and 553c is substantially the same as the first valve 553a, except that the second valve 553b adjusts the flow speed and rate of the second fluid and the third valve 553c adjusts the flow speed and rate of the third fluid, and redundant descriptions thereof are omitted below.

For example, the second fluid supply pipe 551b and the third fluid supply pipe 551c may each have a pipe shape. The second fluid accommodating part 555b and the third fluid accommodating part 555c may each include a storage tank having a space accommodating the second fluid or the third fluid.

According to some implementations, the second thermoregulator 554b may be installed in the second fluid supply pipe 551b and configured to adjust the temperature of the second fluid flowing through the second fluid supply pipe 551b, and the third thermoregulator 554c may be installed in the third fluid supply pipe 551c and configured to adjust the temperature of the third fluid flowing through the third fluid supply pipe 551c.

Each of the second and third thermoregulators 554b and 554c is substantially the same as the first thermoregulator 554a, except that the second thermoregulator 554b adjusts the temperature of the second fluid and the third thermoregulator 554c adjusts the temperature of the third fluid, and redundant descriptions thereof are omitted below.

Accordingly, the first fluid supply pipe 551a, the second fluid supply pipe 551b, and the third fluid supply pipe 551c may independently adjust the temperatures and flowrates of fluids through different valves, thermoregulators, and controllers and respectively provide the fluids to the first brush system 510a, the second brush system 510b, and the third brush system 510c.

For example, referring to FIG. 10A, when the wafer W rotates around the rotation axis parallel with the second horizontal direction (the Y direction), the linear velocity of an outer portion of the wafer W in the radial direction may be greater than that of a central portion of the wafer W in the radial direction. Accordingly, when the first to third brush systems 510a to 510c rotate at the same speed, the friction between the first brush system 510a and the outer portion of the wafer W in the radial direction may be greater than the friction between the third brush system 510c and the central portion of the wafer W.

Accordingly, to uniformly clean the entire area of the wafer W, the third fluid supply pipe 551c of the third brush system 510c close to the central portion of the wafer W may spray the third fluid to the third body 511c at a low flowrate, thereby increasing the friction between the third nodule 512c and the wafer W. In addition, the first fluid supply pipe 551a of the first brush system 510a close to the outer portion of the wafer W may spray the first fluid to the first body 511a at a high flowrate, thereby decreasing the friction between the first nodule 512a and the wafer W. In this case, the second fluid supply pipe 551b of the second brush system 510b may spray the second fluid to the second body 511b at an intermediate flowrate between the flowrate of the first fluid and the flowrate of the third fluid.

To uniformly clean the entire area of the wafer W, the third fluid supply pipe 551c of the third brush system 510c close to the central portion of the wafer W may spray high-temperature third fluid to the third body 511c, thereby increasing the friction between the third nodule 512c and the wafer W. In addition, the first fluid supply pipe 551a of the first brush system 510a close to the outer portion of the wafer W may spray low-temperature first fluid to the first body 511a, thereby decreasing the friction between the first nodule 512a and the wafer W. In this case, the second fluid supply pipe 551b of the second brush system 510b may spray, to the second body 511b, the second fluid at an intermediate temperature between the temperature of the first fluid and the temperature of the third fluid.

By combining the variables of the flowrate and temperature of fluid, the first to third fluid supply pipes 551a to 551c may independently adjust the temperatures and flowrates of the first to third fluids sprayed to the first to third bodies 551a to 551c, according to various environments and conditions involved in the position of the wafer W.

According to some implementations, the first to third fluids may include deionized (DI) water, ultrapure water, or at least one selected from the group consisting of hydrofluoric acid (HF), sulfuric acid (H₃SO₄), nitric acid (HNO₃), phosphoric acid (H₃PO₄), a standard clean-1 (SC-1) solution, an EKC solution, an LAL solution, and a diluted sulfate peroxide solution.

In FIGS. 10D and 10E, the first brush system 510a may include a first housing 514a inside the first body 511a, and the second brush system 510b may include a second housing 514b inside the second body 511b. Additionally, each of the third to sixth brush systems 510c to 510f may include a housing inside corresponding one of the third to sixth bodies 511c to 511f.

The first housing 514a may have a hollow accommodating therein the first to third fluid supply pipes 551a to 551c, and the second housing 514b may have a hollow accommodating therein the second fluid supply pipe 551b and the third fluid supply pipe 551c. In this case, while the third fluid supply pipe 551c may completely pass through the second housing 514b, the second fluid supply pipe 551b may not completely pass through the second housing 514b.

In FIG. 10F, a plurality of holes H may be formed in the second housing 514b. Because the holes H are formed in the second housing 514b, the second fluid ejected from the second fluid supply pipe 551b may be supplied to the second body 511b through the holes H. The holes H may be formed not only in the second housing 514b but also in all housings included in the first to sixth brush modules 510a to 510f.

FIG. 10G is a plan view illustrating the second brush structure RS2 in FIG. 10A according to some implementations. In FIG. 10G, the second brush structure RS2 including the fourth to sixth brush systems 510d to 510f arranged in a line in the vertical direction (the Z direction).

The second brush structure RS2 and the first brush structure RS1 are symmetrical with respect to a virtual boundary line in the first horizontal direction (the X direction) between the first brush structure RS1 and the second brush structure RS2 and have substantially the same operating principle and configuration. Accordingly, redundant descriptions among the descriptions of the first brush structure RS1 are omitted below.

The fourth brush system 510d may further include a fourth fluid supply pipe 551d configured to eject a fourth fluid to the fourth body 511d from inside the fourth body 511d. The fifth brush system 510e may further include a fifth fluid supply pipe 551e configured to eject a fifth fluid to the fifth body 511e from inside the fifth body 511e. The sixth brush system 510f may further include a sixth fluid supply pipe 551f configured to eject a sixth fluid to the sixth body 511f from inside the sixth body 511f. Here, the fourth fluid, the fifth fluid, and the sixth fluid may be of different types according to some implementations.

The fourth fluid supply pipe 551d may be positioned in a central portion of the fourth body 511d in a horizontal view. However, the position of the fourth fluid supply pipe 551d is just an example. According to some implementations, the fourth fluid supply pipe 551d may be positioned in an outer portion of the fourth body 511d.

The fifth fluid supply pipe 551e may be positioned in an outer portion of the fifth body 511e in a horizontal view. However, the position of the fifth fluid supply pipe 551e is just an example. According to some implementations, the fifth fluid supply pipe 551e may be positioned in a central portion of the fifth body 511c.

The sixth fluid supply pipe 551f may be positioned in an outer portion of the sixth body 511f in a horizontal view. However, the position of the sixth fluid supply pipe 551f is just an example. According to some implementations, the sixth fluid supply pipe 551f may be positioned in a central portion of the sixth body 511f.

According to some implementations, an end of the fourth fluid supply pipe 551d may be inside the fourth body 511d. The descriptions of the end of the fourth fluid supply pipe 551d overlaps with the descriptions of the end of the first fluid supply pipe 551a and are thus omitted below.

According to some implementations, the fifth fluid supply pipe 551e may pass through the fourth body 511d, and an end of the fifth fluid supply pipe 551e may be inside the fifth body 511c. The sixth fluid supply pipe 551f may pass through the fourth body 511d and the fifth body 511e, and an end of the sixth fluid supply pipe 551f may be inside the sixth body 511f. The descriptions of the end of the fifth fluid supply pipe 551e overlaps with the descriptions of the end of the second fluid supply pipe 551b and are omitted below. The descriptions of the end of the sixth fluid supply pipe 551f overlaps with the descriptions of the end of the third fluid supply pipe 551c and are omitted below.

The fourth fluid supply pipe 551d may not overlap either the fifth body 511e or the sixth body 511f in the second horizontal direction (the Y direction). The fifth fluid supply pipe 551c may not overlap the sixth body 511f in the second horizontal direction (the Y direction). However, the sixth fluid supply pipe 551f may overlap all the fourth body 511d and the fifth body 511c.

According to some implementations, pores may be formed in the fourth to sixth bodies 511d to 511f and the fourth to sixth nodules 512d to 512f, as described above with reference to FIG. 8. Accordingly, when the fourth to sixth fluid supply pipes 551d, 551e, and 551f respectively spray fluids to the fourth to sixth bodies 511d to 511f, fluids may escape through the pores and may be sprayed onto the wafer W to be cleaned.

According to some implementations, the fourth brush system 510d, the fifth brush system 510c, and the sixth brush system 510f of the second brush structure RS2 may be configured to independently spray fluids to the wafer W. The descriptions of the fluid spray mechanism of the fourth to sixth brush systems 510d to 510f significantly overlap with the descriptions of the fluid spray mechanism of the first to third brush systems 510a to 510c, and redundant descriptions thereof are omitted.

The fourth fluid supply pipe 551d may extend from outside the fourth body 511d and overlap at least a portion of the fourth body 511d. The fourth fluid supply pipe 551d may be connected to a fourth valve 553d, a fourth thermoregulator 554d, a fourth fluid accommodating part 555d, and a fourth controller 556d.

As described above, one end of the fourth fluid supply pipe 551d may be inside the fourth body 511d. The opposite end of the fourth fluid supply pipe 551d may be connected to the fourth fluid accommodating part 555d, and the fourth valve 553d opening and closing the flow of a fluid may be installed in the fourth fluid supply pipe 551d.

According to some implementations, the fourth thermoregulator 554d may be installed in the fourth fluid supply pipe 551d and configured to adjust the temperature of the fourth fluid flowing through the fourth fluid supply pipe 551d.

In FIG. 10B, the controller 556 may include the temperature controller 5561 and the flowrate controller 5562. The temperature controller 5561 of each of the fourth to sixth controllers 556d to 556f may be electrically connected to one of fourth to sixth thermoregulators 554d to 554f and configured to exchange electrical signals for adjusting the temperature of a fluid with one of the fourth to sixth thermoregulators 554d to 554f. The flowrate controller 5562 of each of the fourth to sixth controllers 556d to 556f may be electrically connected to one of fourth to sixth valves 553d to 553f and configured to exchange electrical signals for adjusting the flowrate of a fluid with one of the fourth to sixth valves 553d to 553f.

The fifth fluid supply pipe 551e may extend from outside the fourth body 511d through the fourth body 511d and overlap at least a portion of the fifth body 511e. The fifth fluid supply pipe 551e may be connected to the fifth valve 553c, the fifth thermoregulator 554c, the fifth fluid accommodating part 555c, and the fifth controller 556c. The sixth fluid supply pipe 551f may extend from outside the fourth body 511d through the fourth body 511d and the fifth body 511c and overlap at least a portion of the sixth body 511f. The sixth fluid supply pipe 551f may be connected to the sixth valve 553f, the sixth thermoregulator 554f, the sixth fluid accommodating part 555f, and the sixth controller 556f.

As described above, one end of the fifth fluid supply pipe 551e may be inside the fifth body 511e, and one end of the sixth fluid supply pipe 551f may be inside the sixth body 511f. The opposite end of the fifth fluid supply pipe 551e may be connected to the fifth fluid accommodating part 555e, and the fifth valve 553e opening and closing the flow of a fluid may be installed in the fifth fluid supply pipe 551c. The opposite end of the sixth fluid supply pipe 551f may be connected to the sixth fluid accommodating part 555f, and the sixth valve 553f opening and closing the flow of a fluid may be installed in the sixth fluid supply pipe 551f. Each of the fifth and sixth valves 553c and 553f is substantially the same as the first valve 553a, except that the fifth valve 553c adjusts the flow speed and rate of the fifth fluid and the sixth valve 553f adjusts the flow speed and rate of the sixth fluid, and redundant descriptions thereof are omitted below.

According to some implementations, the fifth thermoregulator 554c may be installed in the fifth fluid supply pipe 551e and configured to adjust the temperature of the fifth fluid flowing through the fifth fluid supply pipe 551e, and the sixth thermoregulator 554f may be installed in the sixth fluid supply pipe 551f and configured to adjust the temperature of the sixth fluid flowing through the sixth fluid supply pipe 551f.

Each of the fifth and sixth thermoregulators 554e and 554f is substantially the same as the first thermoregulator 554a, except that the fifth thermoregulator 554e adjusts the temperature of the fifth fluid and the sixth thermoregulator 554f adjusts the temperature of the sixth fluid, and thus, redundant descriptions thereof are omitted below.

Accordingly, the fourth fluid supply pipe 551d, the fifth fluid supply pipe 551e, and the sixth fluid supply pipe 551f may independently adjust the temperatures and flowrates of fluids through different valves, thermoregulators, and controllers and respectively provide the fluids to the fourth brush module 510d, the fifth brush module 51n0e, and the sixth brush module 510f.

For example, i FIG. 10A, when the fourth to sixth brush systems 510d to 510f rotate at the same speed, the friction between the fourth brush system 510d and the outer portion of the wafer W in the radial direction may be greater than the friction between the sixth brush system 510f and the central portion of the wafer W.

To evenly clean the entire area of the wafer W, the flowrates and speeds of fluids respectively ejected by the fourth to sixth fluid supply pipes 551d to 551f may be independently adjusted. The descriptions of the fourth fluid ejected by the fourth fluid supply pipe 551d may correspond to the descriptions of the first fluid ejected by the first fluid supply pipe 551a. The descriptions of the fifth fluid ejected by the fifth fluid supply pipe 551e may correspond to the descriptions of the second fluid ejected by the second fluid supply pipe 551b. The descriptions of the sixth fluid ejected by the sixth fluid supply pipe 551f may correspond to the descriptions of the third fluid ejected by the third fluid supply pipe 551c.

Accordingly, the detailed descriptions of a mechanism by which the fourth to sixth fluid supply pipes 551d to 551f independently adjust the flowrates and speeds of the third to sixth fluids overlap with the descriptions of a mechanism by which the first to third fluid supply pipes 551a to 551c independently adjust the flowrates and speeds of the first to third fluids and are thus omitted below.

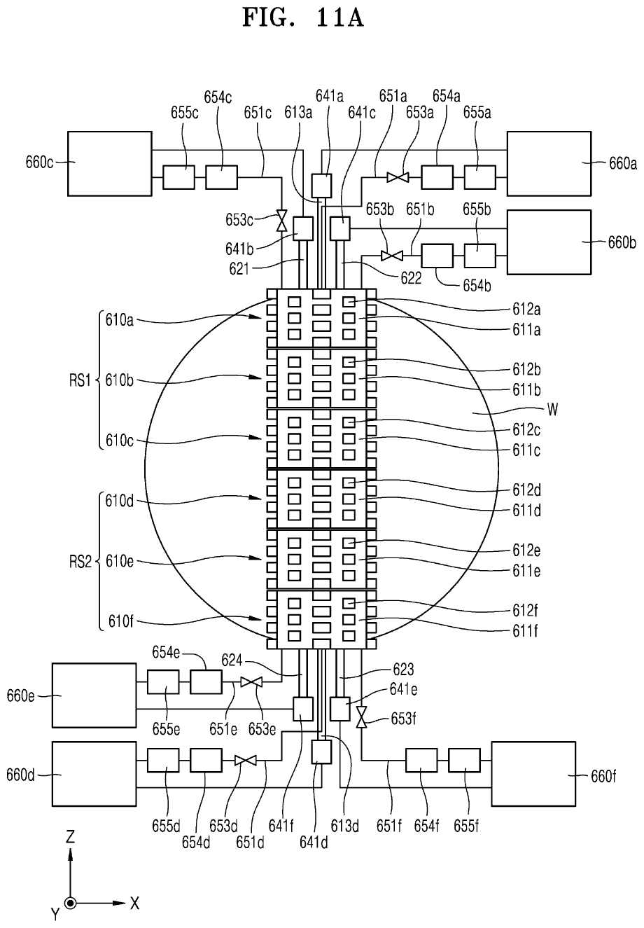

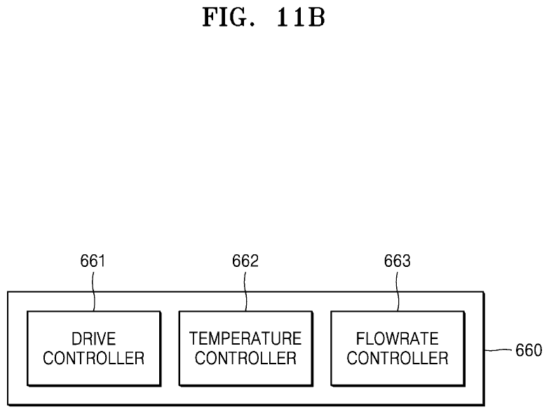

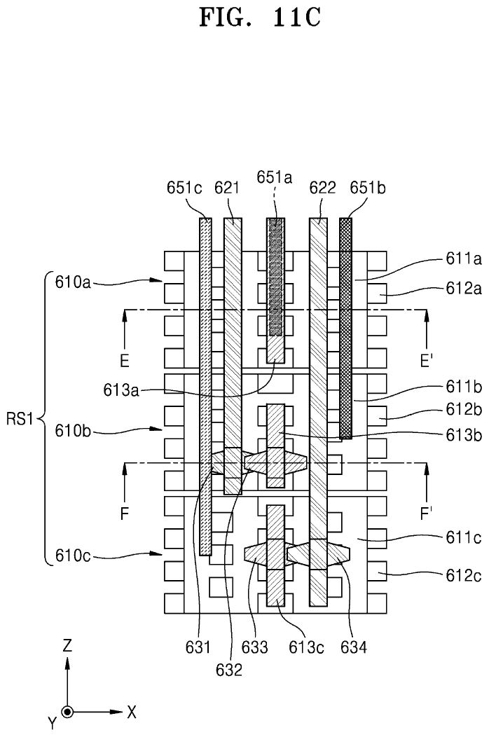

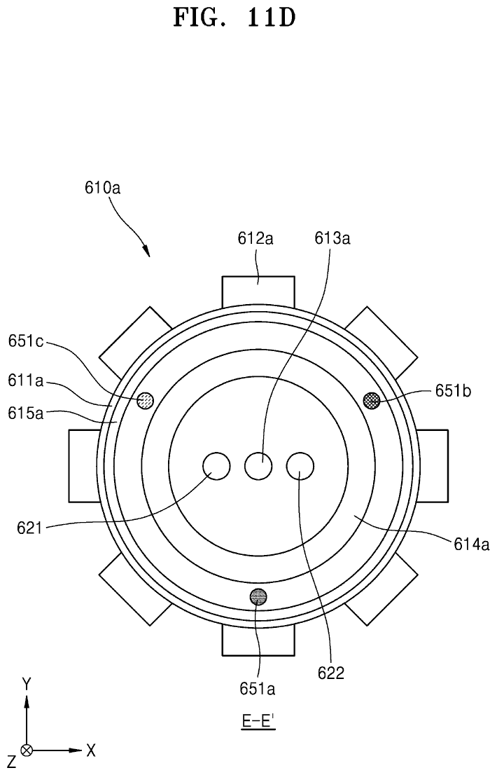

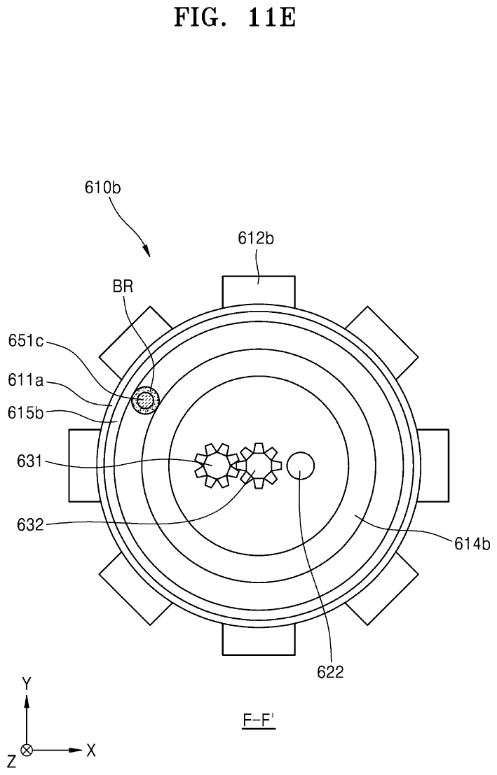

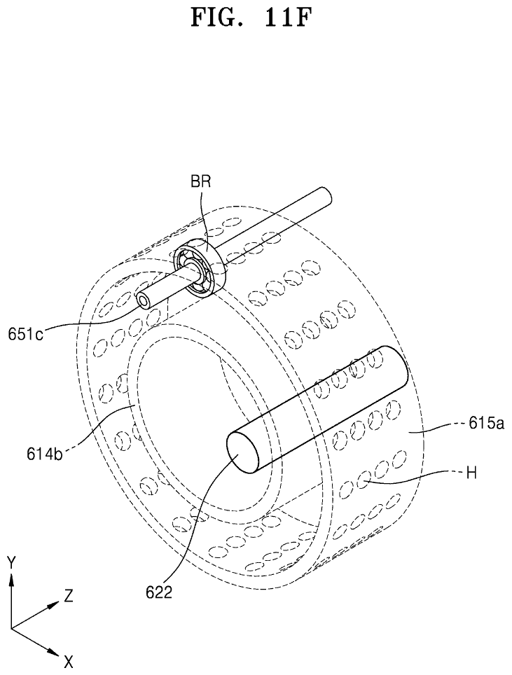

FIG. 11A is a plan view illustrating an example of a wafer cleaning device according to some implementations. FIG. 11B is a diagram illustrating an example of a control system in FIG. 11A according to some implementations.

In FIG. 11A, a wafer cleaning device 600 may include a first brush structure RS1 and a second brush structure RS2, which are arranged in a line in one direction, a plurality of driveshafts (e.g., 613a and 613d), a plurality of transmission shafts (e.g., 621 to 624), a plurality of connectors (e.g., 631 to 634), a plurality of actuators (641a to 641f, a plurality of fluid supply pipes (e.g., 651a to 651f), a plurality of valves (e.g., 653a to 653f), a plurality of thermoregulators (e.g., 654a to 654f), a plurality of fluid accommodating parts (e.g., 655a to 655f), and a plurality of controllers (e.g., 660a to 660f).

The wafer cleaning device 600 of FIGS. 11A to 11F may substantially the same as or similar to the wafer cleaning device 400 of FIGS. 9A to 9F and the wafer cleaning device 500 of FIGS. 10A to 10G, except that the wafer cleaning device 600 includes all elements corresponding to the driveshafts (413a and 413d), the transmission shafts (421 to 424), the connectors (431 to 434), the wires (442a to 442f), and the actuators (441a to 441f) of the wafer cleaning device 400 and all elements corresponding to the fluid supply pipes (551a to 551f), the valves (553a to 553f), the thermoregulators (554a to 554f), and the fluid accommodating parts (555a to 555f) of the wafer cleaning device 500. The functions of the driveshafts (613a and 613d), the transmission shafts (621 to 624), the connectors (631 to 634), and the actuators (641a to 641f) in FIGS. 11A to 11F may be substantially the same as the functions of the driveshafts (413a and 413d), the transmission shafts (421 to 424), the connectors (431 to 434), and the actuators (441a to 441f) in FIGS. 8A to 9F. Similarly, the structures, arrangement, and functions of the fluid supply pipes (651a to 651f), the valves (653a to 653f), the thermoregulators (654a to 654f), and the fluid accommodating parts (655a to 655f) of the wafer cleaning device 600 of FIGS. 11A to 11F may be substantially the same as those of the fluid supply pipes (551a to 551f), the valves (553a to 553f), the thermoregulators (554a to 554f), and the fluid accommodating parts (555a to 555f) in FIGS. 10A to 10F. Therefore, redundant descriptions made with reference to FIGS. 9A to 9F and FIGS. 10A to 10G are omitted below.

The first brush structure RS1 may include a first brush system 610a, a second brush system 610b, and a third brush system 610c, which are arranged in a line in the reverse vertical direction (the −Z direction). The second brush structure RS2 may include a fourth brush system 610d, a fifth brush system 610e, and a sixth brush system 610f, which are arranged in a line in the vertical direction (the Z direction).

The first brush system 610a may include a first body 611a and a first nodule 612a. The second brush system 610b may include a second body 611b and a second nodule 612b. The third brush system 610c may include a third body 611c and a third nodule 612c. The fourth brush system 610d may include a fourth body 611d and a fourth nodule 612d. The fifth brush system 610e may include a fifth body 611e and a fifth nodule 612e. The sixth brush system 610f may include a sixth body 611f and a sixth nodule 612f.

The first to sixth bodies 611a to 611f and the first to sixth nodules 612a to 612f in FIG. 11A are substantially the same as the first to sixth bodies 311a to 311f and the first to sixth nodules 312a to 312f in FIG. 4, and redundant descriptions made above with reference to FIG. 4 are omitted below.

In FIG. 11B, a controller 660 may include a drive controller 661, a temperature controller 662, and a flowrate controller 663. The drive controller 661 of FIG. 11B may perform the same function as each of the first to sixth controllers 443a to 443f in FIG. 9A, the temperature controller 662 and the flowrate controller 663 in FIG. 11B may respectively perform the same functions as the temperature controller 5561 and the flowrate controller 5562 in FIG. 10B. Accordingly, redundant descriptions made about the controllers (443a to 443f) in FIG. 9A and the controller 556 of FIG. 10B are omitted below.

According to some implementations, the first brush system 610a, the second brush system 610b, and the third brush system 610c of the first brush structure RS1 and the fourth brush system 610d, the fifth brush system 610e, and the sixth brush system 610f of the second brush structure RS2 may be configured to independently rotate with the vertical direction (the Z direction) as the rotation axis. The descriptions of the rotation mechanism of the first to sixth brush systems 610a to 610f overlap with the descriptions of the rotation mechanism of the first to sixth brush systems 410a to 410f in FIGS. 9A to 9F and are omitted below.

According to some implementations, the first brush system 610a, the second brush system 610b, and the third brush system 610c of the first brush structure RS1 and the fourth brush system 610d, the fifth brush system 610e, and the sixth brush system 610f of the second brush structure RS2 may be configured to independently spray fluids to the wafer W. The descriptions of the fluid spray mechanism of the first to sixth brush systems 610a to 610f overlap with the descriptions of the fluid spray mechanism of the first to sixth brush systems 510a to 510f in FIGS. 10A to 10G and are omitted below.

The controller 660 may include all the drive controller 661, the temperature controller 662, and the flowrate controller 663 and be configured to simultaneously transmit or receive an operation signal for the rotation mechanism of each of the first to sixth brush systems 610a to 610f and transmit or receive an operation signal for the fluid spray mechanism of each of the first to sixth brush systems 610a to 610f.

FIG. 11C is a plan view illustrating an example of the first brush structure RS1 in FIG. 11A according to some implementations. FIG. 11D is a cross-sectional view taken along line E-E′ in FIG. 11C according to some implementations.

In FIGS. 11C and 11D, the first brush system 610a may further include a first inner housing 614a and a first outer housing 615a. The first inner housing 614a may have a hollow accommodating therein a first driveshaft 613a, a first transmission shaft 621, and a second transmission shaft 622. The first inner housing 614a in FIG. 11D may correspond to the second housing 414b described with reference to FIG. 9E. Accordingly, a groove may be formed in the first driveshaft 613a in FIG. 11D, and the first inner housing 614a may include a rod extending to be in close contact with the first driveshaft 613a. Accordingly, the first inner housing 614a in FIG. 11D may also be configured to integrally rotate with the first driveshaft 613a.

According to some implementations, the first outer housing 615a may have a hollow accommodating therein first to third fluid supply pipes 651a to 651c. In this case, the first to third fluid supply pipes 651a to 651c may be between the outer surface of the first inner housing 614a and the inner surface of the first outer housing 615a. The first outer housing 615a in FIG. 11D may correspond to the first housing 514a described with reference to FIG. 10D.

According to some implementations, the first outer housing 615a may be closely fastened to the first body 611a and integrally rotate with the first body 611a. The first outer housing 615a and the first inner housing 614a may integrally rotate, which is described in detail with reference to FIGS. 11E and 11F below.

FIG. 11E is a cross-sectional view taken along line F-F′ in FIG. 11C according to some implementations. FIG. 11F is a perspective view of an example of a part of the first brush structure RS1 in FIG. 11A.

In FIGS. 11E and 11F, the second brush system 610b may further include a second inner housing 614b, a second outer housing 615b, and a bearing BR. The second inner housing 614b of the second brush system 610b may have a hollow accommodating therein a second driveshaft 613b, the first transmission shaft 621, and the second transmission shaft 622. In the second inner housing 614b in FIG. 11E, a groove may be formed in the second driveshaft 613b in FIG. 11C, and the second inner housing 614b may also include a rod extending to be in close contact with the second driveshaft 613b. Accordingly, the second inner housing 614b in FIG. 11E may also be configured to integrally rotate with the second driveshaft 613b.

According to some implementations, the second outer housing 615b may have a hollow accommodating therein the second and third fluid supply pipes 651b and 651c. In this case, the second and third fluid supply pipes 651b and 651c may be between the outer surface of the second inner housing 614b and the inner surface of the second outer housing 615b.

The bearing BR may surround the third fluid supply pipe 651c between the second outer housing 615b and the second inner housing 614b. The bearing BR may be in close contact with the inner wall of the second outer housing 615b and the outer wall of the second inner housing 614b and configured to deliver the torque of the second inner housing 614b to the second outer housing 615b.

In FIG. 11F, a plurality of holes H may be formed in the second outer housing 615b. Because the holes H are formed in the second outer housing 615b, the second fluid ejected from the second fluid supply pipe 651b may be supplied to the second body 611b through the holes H. The holes H may be formed not only in the second outer housing 615b but also all in outer housings included in the first to sixth brush modules 610a to 610f.

There is only the bearing BR surrounding a fluid supply pipe between the second outer housing 615b and the second inner housing 614b, the wafer cleaning device 600 may also include a bearing surrounding a fluid supply pipe between the first outer housing 615a and the first inner housing 614a. Additionally, the wafer cleaning device 600 may also include a bearing surrounding a fluid supply pipe between a third outer housing and a third inner housing of the third brush system 610c, a bearing surrounding a fluid supply pipe between a fourth outer housing and a fourth inner housing of the fourth brush system 610d, a bearing surrounding a fluid supply pipe between a fifth outer housing and a fifth inner housing of the fifth brush system 610c, and a bearing surrounding a fluid supply pipe between a sixth outer housing and a sixth inner housing of the sixth brush system 610f.

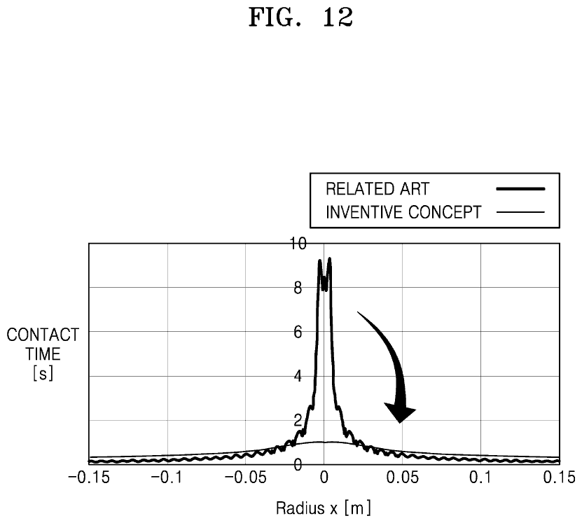

FIG. 12 is a graph illustrating examples of effects of a wafer cleaning device according to some implementations. Descriptions are made with reference to FIG. 12 below. For convenience of descriptions, FIG. 9A is also referred to.

In the graph of FIG. 12, the horizontal axis is a position in the radial direction of the wafer W. Here, a radius of 0 may refer to a position of the exact center of the wafer W having a circular top surface, a radius greater than 0 may refer to a position away from the exact center of the wafer W in one direction, and a radius less than 0 may refer to a position away from the exact center of the wafer W in a direction opposite to the one direction.

In the graph of FIG. 12, the vertical axis represents a contact time between the wafer W and the brush systems (e.g., 410a to 410f) of the wafer cleaning device 400.

In the graph of FIG. 12, the bold solid line represents result values of a known wafer cleaning device, and the light solid line represents result values of a wafer cleaning device according to some implementations.

With respect to the bold solid line, a wafer continuously rotates around a rotation axis parallel with the second horizontal direction (the Y direction) while a brush cylindrically rotates around a rotation axis parallel with the vertical direction (the Z direction). Accordingly, while a central portion of the wafer is in constant contact with the brush, an outer portion of the wafer comes into contact with the brush at each rotation interval. Accordingly, the central portion of the wafer has a long contact time with the brush while the outer portion of the wafer has a short contact time with the brush, which may cause uneven cleaning of the wafer.

With respect to the light solid line, in some implementations, brush systems (e.g., the third brush system 410c and the sixth brush system 410f) close to the center of the wafer may have a low rotation speed while brush systems (e.g., the first brush system 410a and the fourth brush system 410d) close to the outer portion of the wafer may have a high rotation speed, thereby evenly maintaining the contact time between the wafer and the brush systems. As a result, according to some implementations, the wafer cleaning device may evenly clean the entire area of the wafer.

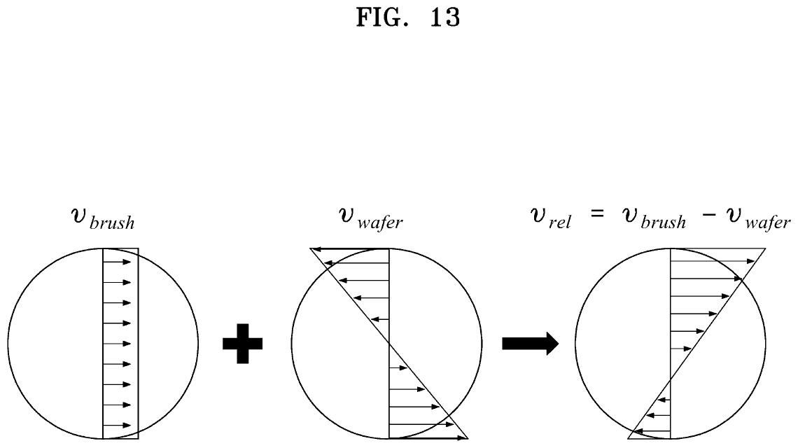

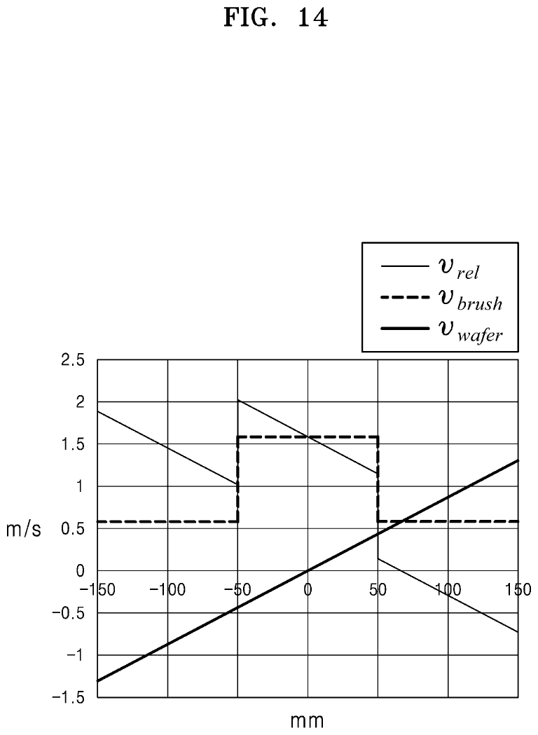

FIG. 13 is a diagram illustrating examples of a relative velocity between a wafer and a brush system. FIG. 14 is a graph illustrating examples of relative velocity of a position in the radial direction of a wafer according to some implementations. For convenience of descriptions, FIG. 9A is also referred to.

In FIGS. 9A and 13, a part on the left of the diagram represents the linear velocities of the first to sixth brush systems 410a to 410f. Here, it is assumed that the first to sixth brush systems 410a to 410f rotate at the same speed.

A part at the center of the diagram of FIG. 13 represents linear velocities at different positions in the wafer W. Here, it is assumed that the wafer W rotates counterclockwise.

A part on the left of the diagram of FIG. 13 represents the relative velocities of the first to sixth brush systems 410a to 410f with respect to the rotating wafer W. The relative velocity of each of the first to sixth brush systems 410a to 410f with respect to the rotating wafer W may be defined as a linear velocity of each of the first to sixth brush systems 410a to 410f minus a linear velocity of the rotating wafer W.

The horizontal axis of the graph of FIG. 14 is a position in the radial direction of the wafer W. Here, a radius of 0 may refer to a position of the exact center of the wafer W having a circular top surface, a radius greater than 0 may refer to a position away from the exact center of the wafer W in one direction, and a radius less than 0 may refer to a position away from the exact center of the wafer W in a direction opposite to the one direction.

The vertical axis of the graph of FIG. 14 is velocity. In the graph, the thin solid line represents the relative velocities of the first to sixth brush systems 410a to 410f with respect to the rotating wafer W, the dashed line represents the linear velocities of the first to sixth brush systems 410a to 410f, and the bold solid line represents the linear velocity of the rotating wafer W.

FIG. 14 is a graph illustrating examples of relative velocity of a position in the radial direction of a wafer according to some implementations. In FIG. 14, result values in the case where the rotation speed of the third brush system 410c and the sixth brush system 410f, which are close to the center of the wafer W, is relatively high (e.g., set to about 1.5 m/s) and the rotation speed of the first and second brush systems 410a and 410b and the fourth and fifth brush systems 410d and 410e is relative low (e.g., set to about 0.5 m/s).

In FIG. 14, when the first to sixth brush systems 410a to 410f independently have different rotation speeds, the relative velocities of the first to sixth brush systems 410a to 410f may be different according to a position in the wafer W. Different elements may be formed in different positions on the main surface of the wafer W. Sensitivity to external friction may vary with elements, and local cleaning may be required for each region of the wafer W. When the first to sixth brush systems 410a to 410f have different relative velocities according to their positions in the wafer W, local cleaning for each region of the wafer W may be possible.

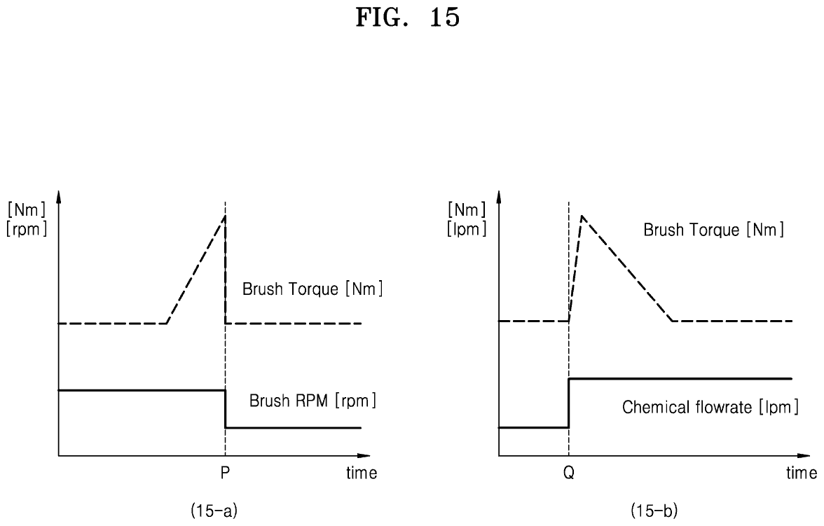

FIG. 15 shows graphs illustrating examples of flowrate of fluid and the revolutions per minute (RPM) of a brush system controlled in response to torque applied to the brush module according to some implementations. In FIG. 15, (15-a) is a graph showing torque applied to a brush system and the RPM of the brush system corresponding to the torque. Referring to (15-a) of FIG. 15, the horizontal axis represents a cleaning time and the vertical axis represents torque and RPM. For convenience of descriptions, FIG. 9A is also referred to.

As shown in (15-a) of FIG. 15, when each of the first to sixth brush systems 410a to 410f rotates at a constant RPM, torque applied to each of the first to sixth brush systems 410a to 410f may be constantly maintained and then increase from a certain time point. When the amount of fluid sprayed on the wafer W is insufficient or a certain layer of an element formed on the wafer W is completely worn out, the friction between the first to sixth brush systems 410a to 410f and the wafer W may increase, thereby increasing torque applied to the first to sixth brush systems 410a to 410f.

According to some implementations, each of the first to sixth actuators 441a to 441f may be configured to sense torque applied to its corresponding one among the first to sixth brush systems 410a to 410f. Each of the first to sixth actuators 441a to 441f may be configured to transmit information about a torque applied to the corresponding one among the first to sixth brush systems 410a to 410f to its corresponding one among the first to sixth controllers 443a to 443f.

When torque applied to each of the first to sixth brush systems 410a to 410f exceeds a threshold at a time point P, each of the first to sixth controllers 443a to 443f may control one of the first to sixth actuators 441a to 441f to decrease the RPM of one of the first to sixth brush systems 410a to 410f. Ideally, the RPM of each of the first to sixth brush systems 410a to 410f may be decreased so that the torque applied to each of the first to sixth brush systems 410a to 410f returns to the torque before the increase of the RPM.

When torque applied to each of the first to sixth brush systems 410a to 410f decreases after being maintained constant, each of the first to sixth controllers 443a to 443f may control one of the first to sixth actuators 441a to 441f to increase the RPM of one of the first to sixth brush systems 410a to 410f.

According to some implementations, to decrease the torque applied to each of the first to sixth brush systems 410a to 410f, the rotation direction of each of the first to sixth brush systems 410a to 410f may be changed.

In FIG. 15, (15-b) is a graph showing torque applied to a brush system and the flowrate of fluid corresponding to the torque. For convenience of descriptions, FIG. 11A is also referred to.

The flowrate of fluid may refer to the flowrate of each of the first to sixth fluids respectively ejected by the first to sixth fluid supply pipes 651a to 651f in FIG. 11A.

In FIG. 15, the torque of the first to sixth brush systems 610a to 610f in (15-b) may also increase due to the same reason as the torque of the first to sixth brush systems 410a to 410f in (15-a) increases. Each of the first to sixth actuators 641a to 641f may also be configured to sense torque applied to its corresponding one among the first to sixth brush systems 610a to 610f. Each of the first to sixth actuators 641a to 641f may be configured to transmit information about torque applied to the corresponding one among the first to sixth brush systems 610a to 610f to its corresponding one among the first to sixth controllers 660a to 660f.

When torque applied to each of the first to sixth brush systems 610a to 610f increases at a time point Q after having been maintained constant, each of the first to sixth controllers 660a to 660f may increase the flowrate of a fluid supplied to one of the first to sixth brush systems 610a to 610f through one of the first to sixth fluid supply pipes 651a to 651f. When the flowrate of a fluid supplied to each of the first to sixth brush systems 610a to 610f increases, the friction between the wafer W and each of the first to sixth brush systems 610a to 610f may decrease, thereby decreasing torque applied to each of the first to sixth brush systems 610a to 610f.

Ideally, the flowrate of a fluid supplied to each of the first to sixth brush systems 610a to 610f may be increased so that the torque applied to each of the first to sixth brush systems 610a to 610f returns to the torque before the increase.

When the torque applied to the first to sixth brush systems 610a to 610f decreases after being maintained constant, each of the first to sixth controllers 660a to 660f may control a corresponding one among the first to sixth actuators 641a to 641f to decrease the flowrate of a fluid supplied through a corresponding one among the first to sixth fluid supply pipes 651a to 651f to a corresponding one among the first to sixth brush systems 660a to 660f.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A wafer cleaning device comprising:
a plurality of brush systems arranged in a line in a first direction and configured to clean a wafer,
wherein each brush system of the plurality of brush systems includes:
a body having a tube shape extending in the first direction;
a nodule arranged on an outer surface of the body; and
a driveshaft extending in the first direction and configured to integrally rotate with the body, and
wherein each brush system of the plurality of brush systems is configured to independently rotate about the first direction as a rotation axis.

2. The wafer cleaning device of claim 1,
wherein the plurality of brush systems include six brush systems sequentially arranged in the first direction, and
wherein respective nodules of the six brush systems have different shapes from one another.

3. The wafer cleaning device of claim 1,
wherein the plurality of brush systems include six brush systems sequentially arranged in the first direction, and
wherein each brush system comprises a different number of nodules.

4. The wafer cleaning device of claim 1,
wherein the plurality of brush systems include six brush systems sequentially arranged in the first direction, and
wherein nodules of the six brush systems comprise different material.

5. The wafer cleaning device of claim 1, comprising:
a chamber providing a space for accommodating the plurality of brush systems; and
a plurality of rollers arranged in the chamber and configured to support the wafer.

6. The wafer cleaning device of claim 1, further comprising:
a chamber providing a space for accommodating the plurality of brush systems; and
a plurality of rollers arranged in the chamber and configured to support the wafer.

7. The wafer cleaning device of claim 1,
wherein the plurality of brush systems include a first brush system, a second brush system, and a third brush system, which are sequentially arranged in the first direction,
wherein the wafer cleaning device further comprises:
a first transmission shaft connected to the driveshaft of the second brush system and configured to transmit a torque to the driveshaft of the second brush system; and
a second transmission shaft connected to the driveshaft of the third brush system and configured to transmit a torque to the driveshaft of the third brush system.

8. The wafer cleaning device of claim 7, further comprising:
a first connector fastened to the first transmission shaft;
a second connector fastened to the driveshaft of the second brush system;
a third connector fastened to the driveshaft of the third brush system; and
a fourth connector fastened to the second transmission shaft,
wherein the second connector is configured to engage with the first connector and receive power, and the third connector is configured to engage with the fourth connector and receive power.

9. The wafer cleaning device of claim 7,
wherein a gap is between a central portion of the body of the first brush system in a radial direction perpendicular to the first direction and a central portion of the body of the second brush system in the radial direction, and
wherein the first brush system includes a boundary nodule arranged on the outer surface of the body of the first brush system in the radial direction and blocking the gap.

10. The wafer cleaning device of claim 1,
wherein each brush system of the plurality of brush systems includes a housing inside the body and having a tube shape including a hollow accommodating therein the driveshaft,
wherein the housing includes a rod extending to the driveshaft, and
wherein the driveshaft includes a groove in close contact with the rod and integrally rotates with the rod.

11. A wafer cleaning device comprising:
a first brush system, a second brush system, and a third brush system that are arranged in a line in a first direction and configured to clean a wafer,
wherein the first brush system includes a first body having a tube shape extending in the first direction, a first nodule arranged on an outer surface of the first body, and a first driveshaft extending in the first direction and configured to integrally rotate with the first body,
wherein the second brush system includes a second body having a tube shape extending in the first direction, a second nodule arranged on an outer surface of the second body, and a second driveshaft extending in the first direction and configured to integrally rotate with the second body, and
wherein the third brush system includes a third body having a tube shape extending in the one direction, a third nodule arranged on an outer surface of the third body, and a third driveshaft extending in the first direction and configured to integrally rotate with the third body, and
wherein the wafer cleaning device comprises:
a first fluid supply pipe inside the first body and configured to eject a first fluid to the first body;
a second fluid supply pipe inside the second body and configured to eject a second fluid to the second body; and
a third fluid supply pipe inside the third body and configured to eject a third fluid to the third body.

12. The wafer cleaning device of claim 11,
wherein an end of the first fluid supply pipe is inside the first body,
wherein the second fluid supply pipe passes through the first body and has an end inside the second body, and
wherein the third fluid supply pipe passes through the first body and the second body and has an end inside the third body.

13. The wafer cleaning device of claim 11, comprising:
a first thermoregulator connected to the first fluid supply pipe and configured to adjust temperature of the first fluid;
a second thermoregulator connected to the second fluid supply pipe and configured to adjust temperature of the second fluid; and
a third thermoregulator connected to the third fluid supply pipe and configured to adjust temperature of the third fluid,
wherein the first thermoregulator, the second thermoregulator, and the third thermoregulator are configured to independently adjust the temperature of the first fluid, the second fluid, and the third fluid, respectively.

14. The wafer cleaning device of claim 11, comprising:
a first valve connected to the first fluid supply pipe and configured to adjust a flowrate of the first fluid;
a second valve connected to the second fluid supply pipe and configured to adjust a flowrate of the second fluid; and
a third valve connected to the third fluid supply pipe and configured to adjust a flowrate of the third fluid;
wherein the first valve, the second valve, and the third valve are configured to independently adjust the flowrates of the first fluid, the second fluid, and the third fluid, respectively.

15. The wafer cleaning device of claim 11,
wherein the first brush system includes a first outer housing inside the first body, the first outer housing having a tube shape and accommodating therein the first fluid supply pipe, the second fluid supply pipe, and the third fluid supply pipe,
wherein the second brush system includes a second outer housing inside the second body, the second outer housing having a tube shape and accommodating therein the second fluid supply pipe and the third fluid supply pipe, and
wherein the third brush system includes a third outer housing inside the third body, the third outer housing having a tube shape and accommodating therein the third fluid supply pipe.

16. The wafer cleaning device of claim 15, wherein a plurality of holes are in an outer surface of each of the first outer housing, the second outer housing, and the third outer housing.

17. The wafer cleaning device of claim 15, wherein the first brush system includes:
a first inner housing located more inwardly than the first fluid supply pipe, the second fluid supply pipe, and the third fluid supply pipe inside the first outer housing; and
a driveshaft extending in the direction in the first inner housing and configured to integrally rotate with the first inner housing.

18. The wafer cleaning device of claim 17, further comprising:
a bearing between the first outer housing and the first inner housing and surrounding the first fluid supply pipe,
wherein the bearing is in contact with an inner wall of the first outer housing and an outer wall of the first inner housing and configured to transmit a torque from the first inner housing to the first outer housing.

19. A wafer cleaning device comprising:
a first brush structure including a first brush system, a second brush system, and a third brush system that are arranged in a line in one direction and configured to clean a wafer; and
a second brush structure including a fourth brush system, a fifth brush system, and a sixth brush system that are arranged from the third brush system in a line in the one direction and configured to clean the wafer,
wherein each of the first brush system, the second brush system, the third brush system, the fourth brush system, the fifth brush system, and the sixth brush system includes:
an inner housing having a tube shape in the first direction;
an outer housing extending in the first direction and having a tube shape having a hollow accommodating the inner housing;
a body extending in the first direction and having a tube shape having a hollow accommodating the outer housing;
a nodule on an outer surface of the body;
a driveshaft in the inner housing and configured to integrally rotate with the body; and
a fluid supply pipe between the inner housing and the outer housing and configured to eject fluid to the body, and
wherein the first brush system, the second brush system, the third brush system, the fourth brush system, the fifth brush system, and the sixth brush system are configured to independently rotate with the first direction as a rotation axis, and the respective fluid supply pipes of the first brush system, the second brush system, the third brush system, the fourth brush system, the fifth brush system, and the sixth brush system are configured to independently eject the fluid.

20. The wafer cleaning device of claim 19, further comprising:
a first transmission shaft connected to the driveshaft of the second brush system and configured to transmit torque to the driveshaft of the second brush system;
a second transmission shaft connected to the driveshaft of the third brush system and configured to transmit torque to the driveshaft of the third brush system;
a third transmission shaft connected to the driveshaft of the fifth brush system and configured to transmit torque to the driveshaft of the fifth brush system; and
a fourth transmission shaft connected to the driveshaft of the sixth brush system and configured to transmit torque to the driveshaft of the sixth brush system,
wherein the fluid supply pipe of the second brush system passes through the first brush system and has an end inside the body of the second brush system,
wherein the fluid supply pipe of the third brush system passes through the first brush system and the second brush system and has an end inside the body of the third brush system,
wherein the fluid supply pipe of the fifth brush system passes through the fourth brush system and has an end inside the body of the fifth brush system, and
wherein the fluid supply pipe of the sixth brush system passes through the fourth brush system and the fifth brush system and has an end inside the body of the sixth brush system.
